(19) United States
(12) Patent Application Publication
(10) Pub. No.: US 2024/0007081 A1
(43) Pub. Date: Jan. 4, 2024

(54) ACOUSTIC WAVE DEVICE

(71) Applicant: Murata Manufacturing Co., Ltd., Nagaokakyo-shi (JP)

(72) Inventors: Hideki IWAMOTO, Nagaokakyo-shi (JP); Sho NAGATOMO, Nagaokakyo-shi (JP)

(21) Appl. No.: 18/229,701

(22) Filed: Aug. 3, 2023

Related U.S. Application Data
(63) Continuation of application No. PCT/JP2022/013626, filed on Mar. 23, 2022.

(30) Foreign Application Priority Data
Mar. 26, 2021 (JP) 2021-053558

(51) Int. Cl. H03H 9/145; H03H 9/25; H03H 9/02

(52) U.S. Cl. CPC H03H 9/14544; H03H 9/25; H03H 9/02818; H03H 9/02559; H03H 9/02992

(57) ABSTRACT

To provide an acoustic wave device capable of reducing or preventing fluctuations in electrical characteristics and reducing or preventing higher-order modes. An acoustic wave device of the present invention includes a support including a support substrate, a piezoelectric layer provided on the support and having a first principal surface and a second principal surface facing each other, a first IDT electrode provided on the first principal surface and including a plurality of electrode fingers, and a second IDT electrode provided on the second principal surface and including a plurality of electrode fingers. The second IDT electrode is embedded in the support. A dielectric film is provided on the first principal surface of the piezoelectric layer to cover the first IDT electrode. When a wavelength defined by an electrode finger pitch of the first IDT electrode is represented by λ, a thickness of the dielectric film is equal to or less than 0.15λ.

### CROSS REFERENCE TO RELATED APPLICATIONS

This application claims the benefit of priority to Japanese Patent Application No. 2021-053558 filed on Mar. 26, 2021 and is a Continuation Application of PCT Application No. PCT/JP2022/013626 filed on Mar. 23, 2022. The entire contents of each application are hereby incorporated herein by reference.

### BACKGROUND OF THE INVENTION

### 1. Field of the Invention

The present invention relates to an acoustic wave device.

### 2. Description of the Related Art

Hitherto, an acoustic wave device has been widely used in a filter of mobile phones, and the like. International Publication No. 2013/021948 cited below discloses an example of an acoustic wave device using a plate wave. In this acoustic wave device, a LiNbO₃ substrate is provided on a support body. The support body is provided with a through-hole. IDT electrodes are provided on both surfaces of the LiNbO₃ substrate in a portion of the LiNbO₃ substrate facing the through-hole.

### SUMMARY OF THE INVENTION

However, in the acoustic wave device described in International Publication No. 2013/021948, a change in the shape of the LiNbO₃ substrate tends to increase as the acoustic wave is excited. Therefore, there is a problem that fluctuations in electrical characteristics of the acoustic wave device are likely to occur. In addition, the occurrence of higher-order modes cannot be sufficiently reduced or prevented.

Preferred embodiments of the present invention provide acoustic wave devices each being capable of reducing or preventing fluctuations in the electrical characteristics and reducing or preventing the higher-order modes.

In a broad aspect of an acoustic wave device according to a preferred embodiment of the present invention, the acoustic wave device includes a support including a support substrate, a piezoelectric layer provided on the support and including a first principal surface and a second principal surface facing each other, a first IDT electrode provided on the first principal surface and including a plurality of electrode fingers, and a second IDT electrode provided on the second principal surface and including a plurality of electrode fingers. The second IDT electrode is embedded in the support, a dielectric film is provided on the first principal surface of the piezoelectric layer to cover the first IDT electrode, and when a wavelength defined by an electrode finger pitch of the first IDT electrode is represented by λ, a thickness of the dielectric film is equal to or less than about 0.15λ.

In another broad aspect of an acoustic wave device according to a preferred embodiment of the present invention, the acoustic wave device includes a support including a support substrate, a piezoelectric layer provided on the support and including a first principal surface and a second principal surface facing each other, a first IDT electrode provided on the first principal surface and including a plurality of electrode fingers, and a second IDT electrode provided on the second principal surface and including a plurality of electrode fingers. The second IDT electrode is embedded in the support and a film covering the first IDT electrode is not provided on the first principal surface of the piezoelectric layer.

According to acoustic wave devices of preferred embodiments of the present invention, it is possible to reduce or prevent fluctuations in the electrical characteristics and to reduce or prevent the higher-order modes.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic elevational cross-sectional view of an acoustic wave device according to a first preferred embodiment of the present invention.

FIG. 2 is a schematic plan view of the acoustic wave device according to the first preferred embodiment of the present invention.

FIG. 3 is a cross-sectional view taken along a line II-II in FIG. 2.

FIG. 4 is a schematic view illustrating the definition of crystal axes of silicon.

FIG. 5 is a schematic view illustrating a (100) plane of silicon.

FIG. 6 is a schematic view illustrating a (110) plane of silicon.

FIG. 7 is a schematic elevational cross-sectional view illustrating a vicinity of a pair of electrode fingers of each of a first IDT electrode and a second IDT electrode in an acoustic wave device according to a first comparative example.

FIG. 8 is a schematic elevational cross-sectional view illustrating a vicinity of a pair of electrode fingers of each of a first IDT electrode and a second IDT electrode in an acoustic wave device according to a second comparative example.

FIG. 9 is a diagram illustrating phase characteristics in the first comparative example and the second comparative example.

FIG. 10 is a diagram illustrating the phase characteristics in the first preferred embodiment of the present invention and the second comparative example.

FIG. 11 is a schematic elevational cross-sectional view of the acoustic wave device according to a first modified example of the first preferred embodiment of the present invention.

FIG. 12 is a diagram illustrating a relationship between a thickness of a dielectric film and a phase of higher-order modes in the first modified example of the first preferred embodiment of the present invention.

FIG. 13 is a diagram illustrating a relationship between the thickness of the dielectric film and Q characteristics in the first modified example of the first preferred embodiment of the present invention.

FIG. 14 is a schematic elevational cross-sectional view illustrating a vicinity of a pair of electrode fingers of each of a first IDT electrode and a second IDT electrode in an acoustic wave device of a third comparative example.

FIG. 15 is a diagram illustrating impedance characteristics on a frequency side lower than a resonant frequency in a main mode of the first preferred embodiment of the present invention and the third comparative example.

FIG. 16 is a diagram illustrating the relationship between C in the Euler angles of a piezoelectric layer and the phase of the higher-order modes in the first preferred embodiment of the present invention and the second comparative example.

FIG. 17 is a diagram illustrating phase characteristics in a second modified example of the first preferred embodiment of the present invention and a fourth comparative example.

FIG. 18 is a diagram illustrating the relationship between θ in the Euler angles of the piezoelectric layer and a phase of the higher-order modes in the second modified example of the first preferred embodiment of the present invention.

FIG. 19 is a diagram illustrating phases of the higher-order modes in the first preferred embodiment and third to fifth modified examples of the first preferred embodiment of the present invention, and the first comparative example.

FIG. 20 is a diagram illustrating a relationship between a combination of materials of the first IDT electrode and the second IDT electrode and an acoustic velocity in the main mode.

FIG. 21 is a diagram illustrating displacement in the piezoelectric layer for each combination of materials of the first IDT electrode and the second IDT electrode.

FIG. 22 is a diagram illustrating a relationship between a combination of materials of the first IDT electrode and the second IDT electrode and a difference between a maximum value and a minimum value of displacement in the piezoelectric layer.

FIG. 23 is a schematic elevational front cross-sectional view for explaining a distance dx.

FIG. 24 is a diagram illustrating a relationship between the distance dx and the resonant frequency.

FIG. 25 is a diagram illustrating a relationship between the distance dx and an anti-resonant frequency.

FIG. 26 is a diagram illustrating a relationship between the distance dx and a fractional bandwidth.

FIG. 27 is a diagram illustrating the phase characteristics when the distance dx is 0λ and when the distance dx is 0.05λ.

FIG. 28 is a diagram illustrating a relationship between the distance dx and a phase of an unnecessary wave that becomes ripples.

FIG. 29 is a schematic elevational cross-sectional view illustrating a vicinity of a pair of electrode fingers of each of a first IDT electrode and a second IDT electrode in an acoustic wave device according to a second preferred embodiment of the present invention.

FIG. 30 is a diagram illustrating phase characteristics in the first modified example and the second modified example of the second preferred embodiment of the present invention, and the second comparative example.

FIG. 31 is a schematic plan view illustrating a configuration of a first IDT electrode according to a third preferred embodiment of the present invention.

FIG. 32 is a diagram illustrating impedance-frequency characteristics of the first preferred embodiment and the third preferred embodiment of the present invention.

FIG. 33 is a schematic plan view of an acoustic wave device according to a first modified example of the third preferred embodiment of the present invention.

FIG. 34 is a schematic plan view of an acoustic wave device according to a second modified example of the third preferred embodiment of the present invention.

FIG. 35 is a schematic plan view of the acoustic wave device according to a third modified example of the third preferred embodiment of the present invention.

FIG. 36 is a schematic elevational cross-sectional view illustrating a vicinity of a pair of electrode fingers of each of a first IDT electrode and a second IDT electrode in an acoustic wave device according to a fourth preferred embodiment of the present invention.

FIG. 37 is a diagram illustrating the phase characteristics in the fourth preferred embodiment of the present invention and the second comparative example.

FIG. 38 is a diagram illustrating a relationship between θ in the Euler angles and a thickness of a piezoelectric layer and an electromechanical coupling coefficient ksaw² in an SH mode in the fourth preferred embodiment of the present invention.

FIG. 39 is a diagram illustrating a relationship between θ in the Euler angles of the piezoelectric layer and a thickness of a dielectric layer and the electromechanical coupling coefficient ksaw² in the SH mode in the fourth preferred embodiment of the present invention.

FIG. 40 is a diagram illustrating a relationship between θ in the Euler angles and a thickness of a lithium niobate layer and the electromechanical coupling coefficient ksaw² in the SH mode.

FIG. 41 is a schematic elevational cross-sectional view illustrating a vicinity of a pair of electrode fingers of each of a first IDT electrode and a second IDT electrode in an acoustic wave device according to a fifth preferred embodiment of the present invention.

FIG. 42 is a diagram illustrating the phase characteristics in the fifth preferred embodiment of the present invention and the second comparative example.

### DETAILED DESCRIPTION OF THE PREFERRED EMBODIMENTS

Hereinafter, specific preferred embodiments of the present invention will be described with reference to the accompanying drawings to clarify the present invention.

It should be noted that each of the preferred embodiments described in the present specification are merely examples, and partial replacement or combination of configurations is possible between different preferred embodiments.

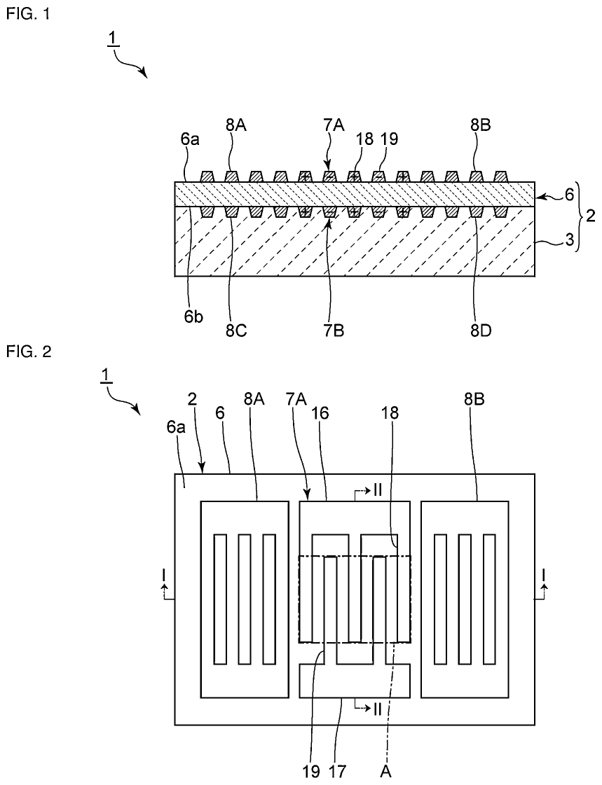

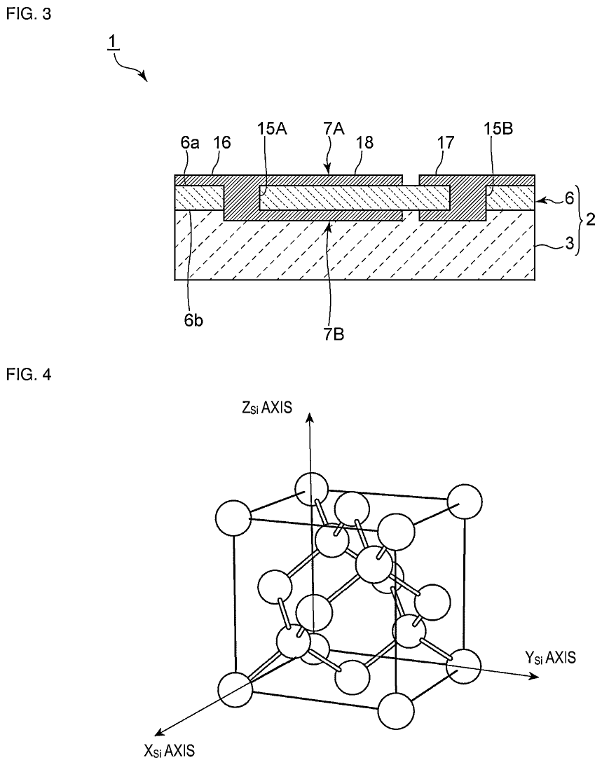

FIG. 1 is a schematic elevational cross-sectional view of an acoustic wave device according to a first preferred embodiment of the present invention. FIG. 2 is a schematic plan view of the acoustic wave device according to the first preferred embodiment of the present invention. FIG. 3 is a cross-sectional view taken along a line II-II in FIG. 2. Note that FIG. 1 is a cross-sectional view taken along a line I-I in FIG. 2. Signs of + and − in FIG. 1 schematically indicate the relative magnitude of a potential.

As illustrated in FIG. 1, the acoustic wave device 1 includes a piezoelectric substrate 2. The piezoelectric substrate 2 includes a support substrate 3 and a piezoelectric layer 6. To be more specific, the piezoelectric layer 6 is directly provided on the support substrate 3. The support substrate 3 is referred to as a support in description of preferred embodiments of the present invention. However, the support may be a multilayer body including the support substrate 3.

The piezoelectric layer 6 includes a first principal surface 6a and a second principal surface 6b. The first principal surface 6a and the second principal surface 6b face each other. A first IDT electrode 7A is provided on the first principal surface 6a. A second IDT electrode 7B is provided on the second principal surface 6b. The first IDT electrode 7A and the second IDT electrode 7B face each other with the piezoelectric layer 6 in between.

The second principal surface 6b of the piezoelectric layer 6 is bonded to the support substrate 3 which is a support. The second IDT electrode 7B is embedded in the support substrate 3. In other words, the support substrate 3 includes a portion facing the second IDT electrode 7B.

An acoustic wave is excited by applying an AC voltage to the first IDT electrode 7A and the second IDT electrode 7B. The acoustic wave device 1 uses a surface wave in the SH mode as a main mode. However, the main mode is not limited to the SH mode, and another mode may be used as the main mode. On the first principal surface 6a of the piezoelectric layer 6, a pair of reflectors 8A and 8B are provided on both sides of the first IDT electrode 7A in an acoustic wave propagation direction. Similarly, a pair of reflectors 8C and 8D are provided on the second principal surface 6b on both sides of the second IDT electrode 7B in the acoustic wave propagation direction. The reflectors 8A, 8B, 8C, and 8D may have the same potential as the first IDT electrode 7A, the same potential as the second IDT electrode 7B, or the same potential as both of the first IDT electrode 7A and the second IDT electrode 7B. Alternatively, they may be floating electrodes. As described above, the acoustic wave device 1 of the present preferred embodiment is a surface acoustic wave resonator. However, an acoustic wave device according to a preferred embodiment of the present invention is not limited to an acoustic wave resonator, and may be a filter device or a multiplexer including a plurality of acoustic wave resonators.

As illustrated in FIG. 2, the first IDT electrode 7A includes a first busbar 16, a second busbar 17, a plurality of first electrode fingers 18, and a plurality of second electrode fingers 19. The first busbar 16 and the second busbar 17 face each other. One end of each of the plurality of first electrode fingers 18 is connected to the first busbar 16. One end of each of the plurality of second electrode fingers 19 is connected to the second busbar 17. The plurality of first electrode fingers 18 and the plurality of second electrode fingers 19 are interdigitated with each other.

Similar to the first IDT electrode 7A, the second IDT electrode 7B includes a pair of busbars and a plurality of electrode fingers. The first IDT electrode 7A and the second IDT electrode 7B have the same electrode finger pitch. Note that the electrode finger pitch is a distance between the centers of adjacent ones of the electrode fingers. In the present specification, the phrase “the electrode finger pitches are the same” includes a case where the electrode finger pitches are different within an error range that does not affect the electrical characteristics of the acoustic wave device. As illustrated in FIG. 1, the cross-sectional shape of each of the electrode fingers of the first IDT electrode 7A and the second IDT electrode 7B is trapezoidal. However, the cross-sectional shape of each of the electrode fingers is not limited to that described above, and may be, for example, a rectangle.

The first IDT electrode 7A, the second IDT electrode 7B, the reflector 8A, the reflector 8B, the reflector 8C, and the reflector 8D are made of Al. However, the materials of each of the IDT electrodes and each of the reflectors are not limited to the material described above. Alternatively, each of the IDT electrodes and each of the reflectors may be formed of a laminated metal film. Note that, in the present specification, when it is described that the IDT electrode or the like is made of a specific material such as Al, a case where the IDT electrode or the like contains a very small amount of impurities that do not affect the electrical characteristics of the acoustic wave device is also included.

In the first IDT electrode 7A, a region in which adjacent ones of the electrode fingers overlap each other when viewed from the acoustic wave propagation direction is an intersection region A. Similarly, the second IDT electrode 7B also includes an intersection region. The intersection region A of the first IDT electrode 7A and the intersection region of the second IDT electrode 7B overlap each other in plan view. To be more specific, the center of the plurality of electrode fingers in the intersection region A of the first IDT electrode 7A and the center of the plurality of electrode fingers in the intersection region of the second IDT electrode 7B overlap each other in plan view. However, it is sufficient that at least a portion of the plurality of electrode fingers of the first IDT electrode 7A and at least a portion of the plurality of electrode fingers of the second IDT electrode 7B overlap each other in plan view. In other words, it is sufficient if the overlapping state is within an error range in which the electrical characteristics of the acoustic wave device are not affected. A deviation due to manufacturing variations is regarded as being overlapped. Here, plan view refers to a direction viewed from above in FIG. 1.

As illustrated in FIG. 3, the acoustic wave device 1 includes a first through electrode 15A and a second through electrode 15B. The first through electrode 15A and the second through electrode 15B penetrate the piezoelectric layer 6. The first through electrode 15A connects the first busbar 16 of the first IDT electrode 7A and one busbar of the second IDT electrode 7B. The second through electrode 15B connects the second busbar 17 of the first IDT electrode 7A and the other busbar of the second IDT electrode 7B. With this, the electrode fingers facing each other with the piezoelectric layer 6 in between have the same potential. However, the busbars may be connected to the same signal potential by wiring other than corresponding one of the through electrodes.

As illustrated in FIG. 1, the potential of the plurality of first electrode fingers 18 is relatively higher than the potential of the plurality of second electrode fingers 19. However, the potential of the plurality of second electrode fingers 19 may be relatively higher than the potential of the plurality of first electrode fingers 18.

One of the unique features of the present preferred embodiment is that the second IDT electrode 7B are embedded in the support substrate 3 serving as a support. As a result, since the piezoelectric layer 6 is supported by the support substrate 3 also in a portion where the acoustic wave is excited, the shape of the piezoelectric layer 6 is not easily deformed, and it is possible to reduce or prevent the fluctuations of the electrical characteristics. In addition, since the second IDT electrode 7B is embedded in the support, higher-order modes can be leaked to a support side. As a result, the higher-order modes can be further reduced or prevented. Details of the effect of reducing or preventing the higher-order modes will be described below together with details of the configuration of the present preferred embodiment.

The piezoelectric layer 6 is a lithium tantalate layer. More specifically, cut-angles of lithium tantalate used for the piezoelectric layer 6 is 30° Y-cut X-propagation, for example. However, the material and the cut-angles of the piezoelectric layer 6 are not limited to those described above. The piezoelectric layer 6 may be, for example, a lithium niobate layer. The piezoelectric layer 6 has crystal axes (X_{Li}, Y_{Li}, Z_{Li}).

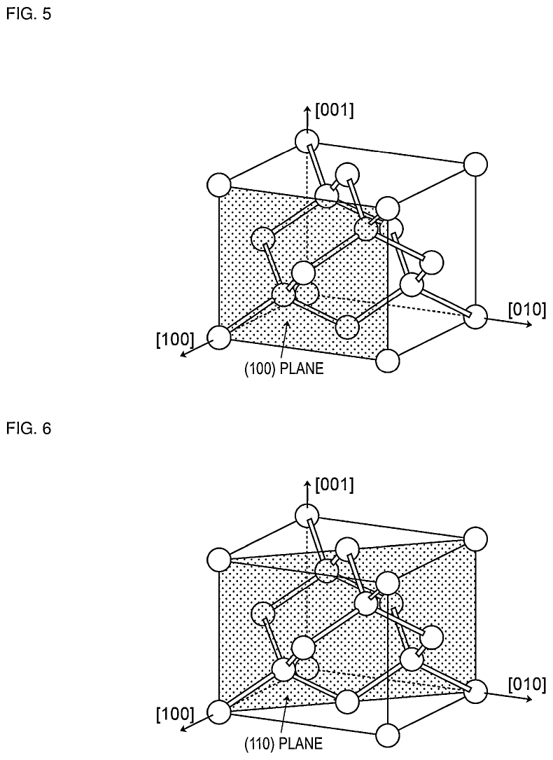

The support substrate 3 is a silicon substrate. As illustrated in FIG. 4, silicon has a diamond structure. In the present specification, the crystal axes of silicon of the silicon substrate is (X_{Si}, Y_{Si}, Z_{Si}). In silicon, the X_{Si} axis, the Y_{Si} axis and the Z_{Si} axis are equivalent to each other due to the symmetry of the crystal structure. In the present preferred embodiment, a plane orientation of the support substrate 3 is (100). The plane orientation of (100) indicates that the substrate is cut along a (100) plane orthogonal to the crystal axis represented by Miller Indices [100] in the crystal structure of silicon having the diamond structure. In the (100) plane, the (100) plane is 4-fold symmetry, and an equivalent crystal structure is obtained by 90° rotation. Note that the (100) plane is the plane illustrated in FIG. 5.

The support substrate 3 and the piezoelectric layer 6 are laminated so that the X_{Li} axis direction and an Si [110] direction are parallel to each other. The Si [110] direction is a direction orthogonal to a (110) plane illustrated in FIG. 6. However, the orientation relationship between the support substrate 3 and the piezoelectric layer 6 is not limited to the above. The plane orientation, the propagation direction, and the material of the support substrate 3 are also not particularly limited. For example, glass, a quartz crystal, alumina, or the like may be used in the support substrate 3.

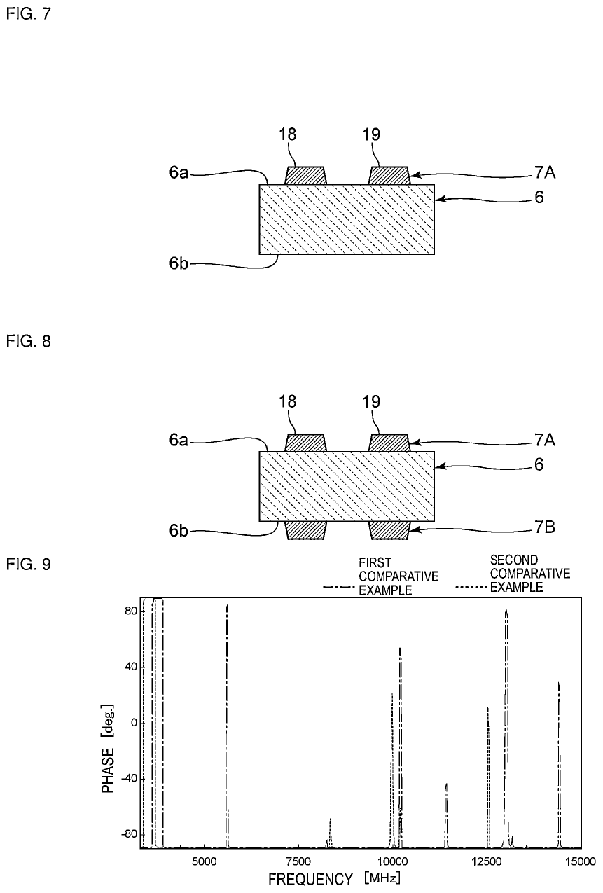

Hereinafter, it will be described that the higher-order modes can be reduced or prevented in the present preferred embodiment by comparing the present preferred embodiment, the first comparative example, and the second comparative example. As illustrated in FIG. 7, the first comparative example is different from the first preferred embodiment in that the second IDT electrode is not provided. In addition, the first comparative example is different from the first preferred embodiment in that a portion of the piezoelectric layer 6 overlapping the intersection region in plan view is not laminated on the support substrate. As illustrated in FIG. 8, the second comparative example is different from the first preferred embodiment in that the second IDT electrode 7B is not embedded in the support substrate. Further, the second comparative example is different from the first preferred embodiment in that a portion of the piezoelectric layer 6 overlapping the intersection region in plan view is not laminated on the support substrate.

In the first preferred embodiment, the first comparative example, and the second comparative example, phase characteristics were compared by performing simulation. Design parameters of each acoustic wave device were as follows. Note that, in the first comparative example and the second comparative example, the portion of the piezoelectric layer 6 that overlaps the intersection region in plan view is not laminated on the support substrate. Therefore, in each of the comparative examples, design parameters of the support substrate are not set.

Design parameters of a non-limiting example of the acoustic wave device 1 of the first preferred embodiment are as follows. Note that, in the first IDT electrode 7A and the second IDT electrode 7B, the electrode fingers overlapping each other in plan view have the same potential. A wavelength defined by the electrode finger pitches of the first IDT electrode 7A and the second IDT electrode 7B is λ.
Support substrate 3; material: Si, plane orientation: (100) plane
Piezoelectric layer 6; material: LiTaO₃, cut-angles: 30° Y-cut X-propagation, thickness: 0.2λ
Orientation relationship between the support substrate 3 and the piezoelectric layer 6; the Si [110] direction and the X_{Li} axis direction are parallel to each other.
First IDT electrode 7A; material: Al, thickness: 0.07λ, duty ratio: 0.5
Second IDT electrode 7B; material: Al, thickness: 0.07λ, duty ratio: 0.5
Wavelength λ: 1 μm

Design parameters of the acoustic wave device of the first comparative example are as follows.
Piezoelectric layer 6; material: LiTaO₃, cut-angles: 30° Y-cut X-propagation, thickness: 0.2λ
First IDT electrode 7A; material: Al, thickness: 0.07λ, duty ratio: 0.5
Wavelength λ: 1 μm

Design parameters of the acoustic wave device of the second comparative example are as follows. Note that, in the first IDT electrode 7A and the second IDT electrode 7B, the electrode fingers overlapping each other in plan view have the same potential.
Piezoelectric layer 6; material: LiTaO₃, cut-angles: 30° Y-cut X-propagation, thickness: 0.2λ
First IDT electrode 7A; material: Al, thickness: 0.07λ, duty ratio: 0.5
Second IDT electrode 7B; material: Al, thickness: 0.07λ, duty ratio: 0.5
Wavelength λ: 1 μm

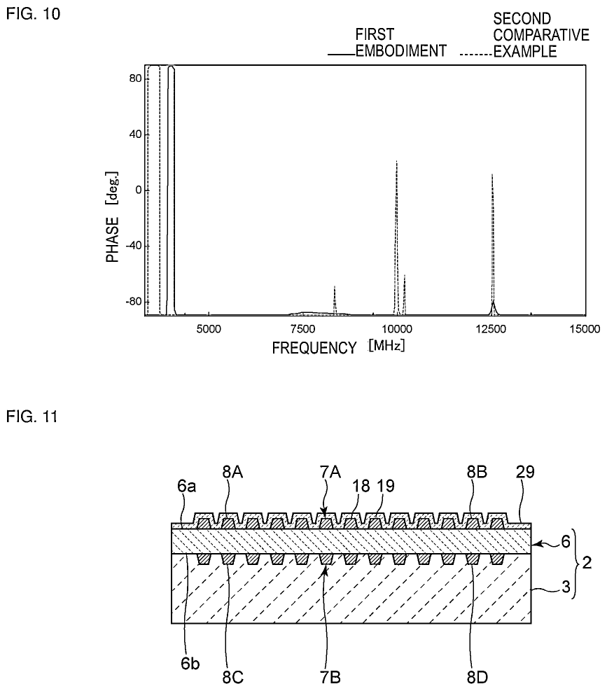

FIG. 9 is a diagram illustrating the phase characteristics in the first comparative example and the second comparative example. FIG. 10 is a diagram illustrating the phase characteristics in the first preferred embodiment and the second comparative example.

As illustrated in FIG. 9, in the first comparative example, a plurality of higher-order modes is generated in a wide frequency band. In the second comparative example, the higher-order modes are reduced or prevented around 5500 MHz. However, also in the second comparative example, a plurality of higher-order modes is generated in a wide frequency band except for around 5500 MHz. As described above, even when the first IDT electrode 7A and the second IDT electrode 7B face each other, the higher-order modes cannot be sufficiently reduced or prevented.

On the other hand, as illustrated in FIG. 10, in the first preferred embodiment, the higher-order modes are reduced or prevented in a wide frequency band. In the first preferred embodiment, the first IDT electrode 7A and the second IDT electrode 7B face each other, and the second IDT electrode 7B is embedded in the support substrate 3. Thereby, the higher-order modes can be leaked to a support substrate 3 side. Thus, the higher-order modes can be effectively reduced or prevented.

In the first preferred embodiment, a film covering the first IDT electrode 7A is not provided on the first principal surface 6a of the piezoelectric layer 6. Accordingly, the main mode can be efficiently excited. However, the present invention is not limited to the configuration described above.

FIG. 11 is a schematic elevational cross-sectional view of the acoustic wave device according to a first modified example of the first preferred embodiment.

As in a first modified example illustrated in FIG. 11, a dielectric film 29 may be provided on the first principal surface 6a of the piezoelectric layer 6 so as to cover the first IDT electrode 7A. In the present modified example, the dielectric film 29 is a silicon oxide film. However, the material of the dielectric film 29 is not limited to silicon oxide, for example, silicon nitride, silicon oxynitride, tantalum pentoxide, amorphous silicon, polycrystalline silicon, aluminum oxide, aluminum nitride, silicon carbide, or the like may be used. Since the first IDT electrode 7A is protected by the dielectric film 29, the first IDT electrode 7A is less likely to be damaged.

Here, in the acoustic wave device of the present modified example, relationships between a thickness of the dielectric film 29 and each of a phase and a Q factor of the higher-order modes were obtained by performing a simulation. Design parameters of a non-limiting example of the acoustic wave device are as follows.
Support substrate 3; material: Si, plane orientation: (100) plane
Piezoelectric layer 6; material: LiTaO₃, cut-angles: 30° Y-cut X-propagation, thickness: 0.2λ
Orientation relationship between the support substrate 3 and the piezoelectric layer 6; the Si [110] direction and the X_{Li} axis direction are parallel to each other.
First IDT electrode 7A; material: Al, thickness: 0.07λ, duty ratio: 0.5
Second IDT electrode 7B; material: Al, thickness: 0.07λ, duty ratio: 0.5
Wavelength λ: 1 μm
Dielectric film 29: material: SiO₂, thickness: varied in increments of 0.0175λ within a range being equal to or more than 0.015λ and equal to or less than 0.05λ, and varied in increments of 0.025λ within a range being equal to or more than 0.05λ and equal to or less than 0.25λ.

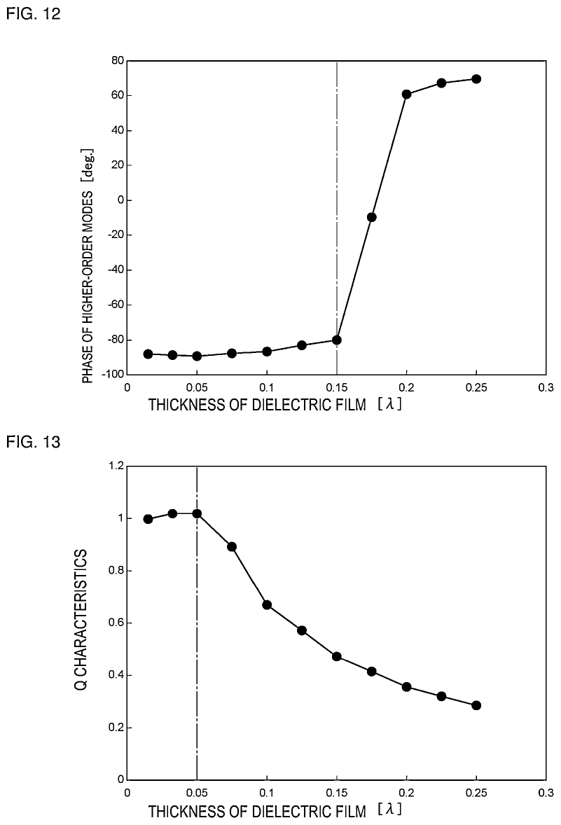

FIG. 12 is a diagram illustrating a relationship between thicknesses of the dielectric film and phases of the higher-order modes in the first modified example of the first preferred embodiment. The phases of the higher-order modes illustrated in FIG. 12 are the phases of the higher-order modes in the range from 5000 MHz to 7000 MHz.

As illustrated in FIG. 12, in the present modified example, the phases of the higher-order modes are equal to or less than about 70 dB. On the other hand, in the first comparative example illustrated in FIG. 9, the higher-order modes in the range from 5000 MHz to 7000 MHz are approximately 85 dB. As described above, in the present modified example, the higher-order modes are more reduced or prevented compared to the first comparative example. In addition, as illustrated in FIG. 12, it is understood that as the thickness of the dielectric film 29 decreases, the higher-order modes are reduced or prevented more. This is because the thinner the thickness of the dielectric film 29, the more difficult for the dielectric film 29 to confine the higher-order modes therein. When the thickness of the dielectric film 29 is equal to or less than about 0.15λ, the higher-order modes are equal to or less than about −80 dB, for example. Therefore, the thickness of the dielectric film 29 is preferably equal to or less than about 0.15λ, for example. As a result, the higher-order modes can be further reduced or prevented.

FIG. 13 is a diagram illustrating a relationship between the thickness of the dielectric film and Q characteristics in the first modified example of the first preferred embodiment. Note that when the thickness of the dielectric film 29 is about 0.015 λ, the Q characteristics are set to a reference value of 1.

As illustrated in FIG. 13, it is understood that the thinner the dielectric film 29 is, the higher the Q characteristics is. In the present preferred embodiment, the Q characteristics of the piezoelectric layer 6 is higher than the Q characteristics of the dielectric film 29. Therefore, as the dielectric film 29 becomes thinner, the ratio of the portion having the high Q characteristics increases in a multilayer body of the piezoelectric layer 6 and the dielectric film 29. Thus, the above relationship is established. When the thickness of the dielectric film 29 is equal to or less than about 0.05λ, the Q characteristics are equal to or more than 1. Therefore, the thickness of the dielectric film 29 is preferably equal to or less than about 0.05λ, for example. According to this, the Q characteristics can be further improved.

Referring back to FIG. 1, as in the first preferred embodiment, it is preferable that the first IDT electrode 7A and the second IDT electrode 7B face each other with the piezoelectric layer 6 in between, and that the electrode fingers overlapping each other in plan view be connected to the same potential. In this case, the symmetry of electric fields generated from the first IDT electrode 7A and the second IDT electrode 7B can be enhanced. As a result, the higher-order modes can be further reduced or prevented.

Further, in the first preferred embodiment, since the first IDT electrode 7A and the second IDT electrode 7B face each other with the piezoelectric layer 6 in between, electrostatic capacitance can be increased. Thus, even when the first IDT electrode 7A and the second electrode 7B are reduced in size, the desired electrostatic capacitance can be obtained. Therefore, the acoustic wave device 1 can be made smaller. This will be described by comparing the first preferred embodiment and the third comparative example. As illustrated in FIG. 14, the third comparative example is different from the first preferred embodiment in that the second IDT electrode is not provided.

In the first preferred embodiment and the third comparative example, impedance characteristics were compared by performing simulation. The lower the impedance, the electrostatic capacitance increases. Design parameters of the acoustic wave device according to the first preferred embodiment were the same as those used to obtain the phase characteristics described above. Design parameters of the third comparative example were the same as those of the first preferred embodiment except that the second IDT electrode 7B was not provided.

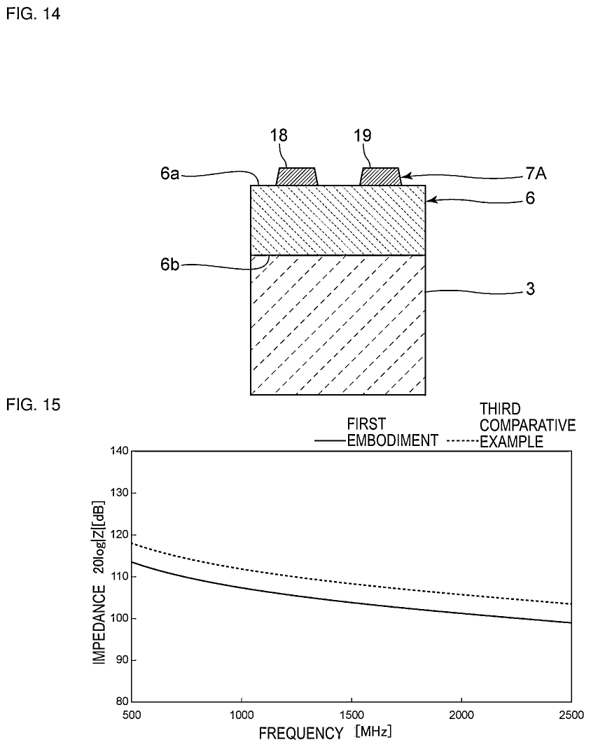

FIG. 15 is a diagram illustrating the impedance characteristics on a frequency side lower than a resonant frequency in the main mode in the first preferred embodiment and the third comparative example.

As illustrated in FIG. 15, it is understood that the impedance in the first preferred embodiment is lower than the impedance in the third comparative example. Therefore, in the first preferred embodiment, it is possible to increase the electrostatic capacitance and to reduce the size of the acoustic wave device 1.

In the first preferred embodiment, the thickness of the piezoelectric layer 6 is equal to or less than about 2λ, for example. The thickness of the piezoelectric layer 6 is preferably equal to or less than about 1λ, for example. With this, the higher-order modes can be more reliably reduced or prevented. However, the thickness of the piezoelectric layer 6 is not limited to the above.

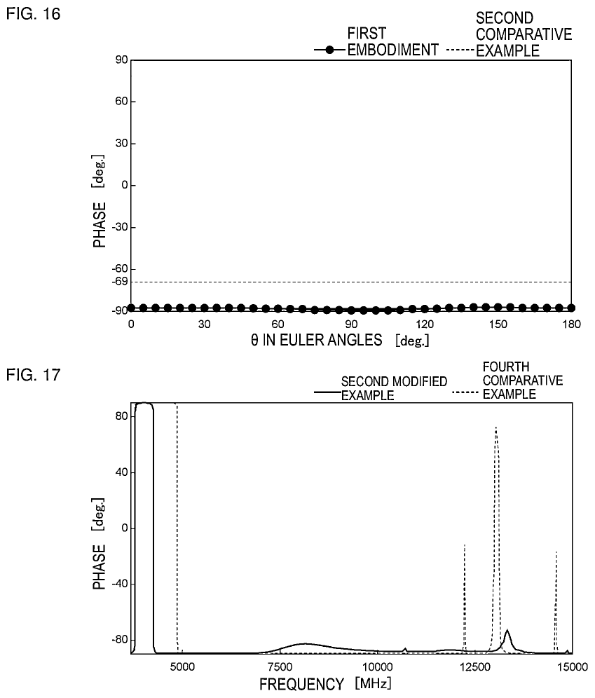

It will be described below that the higher-order modes can be reduced or prevented regardless of the cut-angles of the piezoelectric layer 6. The relationship between θ in the Euler angles (φ, θ, ψ) of the piezoelectric layer 6 and the phase of the higher-order modes around 8400 MHz was obtained by simulation. Note that θ was varied in increments of 5 deg. within a range being equal to or more than 0 deg. and equal to or less than 180 deg. φ and ψ were set to 0°. However, both φ and ψ may be acceptable within a range of ±10°. In FIG. 16, the result is illustrated together with the result of the second comparative example for reference.

FIG. 16 is a diagram illustrating a relationship between θ in the Euler angles of the piezoelectric layer and the phase of the higher-order modes in the first preferred embodiment and the second comparative example. The broken line in FIG. 16 indicates the phases of the higher-order modes around 8400 MHz in the second comparative example illustrated in FIG. 10.

As illustrated in FIG. 16, in the first preferred embodiment, the higher-order modes can be reduced or prevented regardless of θ in the Euler angles of the piezoelectric layer 6.

Note that the piezoelectric layer 6 may be a lithium niobate layer. In this case as well, fluctuations in the electrical characteristics can be reduced or prevented, and also the higher-order modes can be reduced or prevented. This will be described by comparing the second modified example of the first preferred embodiment with the fourth comparative example. As described with reference to FIG. 1, the second modified example is different from the first preferred embodiment only in that the piezoelectric layer 6 is a lithium niobate layer. The fourth comparative example is different from the second modified example in that the second IDT electrode is not embedded in the support substrate. Further, the fourth comparative example is different from the second modified example in that a portion of the piezoelectric layer overlapping the intersection region in plan view is not laminated on the support substrate.

FIG. 17 is a diagram illustrating the phase characteristics in a second modified example of the first preferred embodiment and a fourth comparative example.

As illustrated in FIG. 17, in the fourth comparative example, a plurality of higher-order modes is generated in a wide frequency band. On the other hand, in the second modified example of the first preferred embodiment, it is understood that the higher-order modes can be reduced or prevented in a wide frequency band. In addition, in the present modified example, as in the first preferred embodiment, the piezoelectric layer 6 is supported by the support substrate 3 also in a portion where an acoustic wave is excited. As a result, the shape of the piezoelectric layer 6 is less likely to be deformed, and fluctuations in the electrical characteristics can be reduced or prevented.

It will be described below that even when the piezoelectric layer 6 is a lithium niobate layer, the higher-order modes can be reduced or prevented regardless of the cut-angles. The relationship between θ in the Euler angles (β, θ, ψ) of the lithium niobate layer and the phase of the higher-order modes around 10500 MHz was obtained by simulation. Note that θ was varied in increments of 5 deg. within a range being equal to or more than 0 deg. and equal to or less than 180 deg.

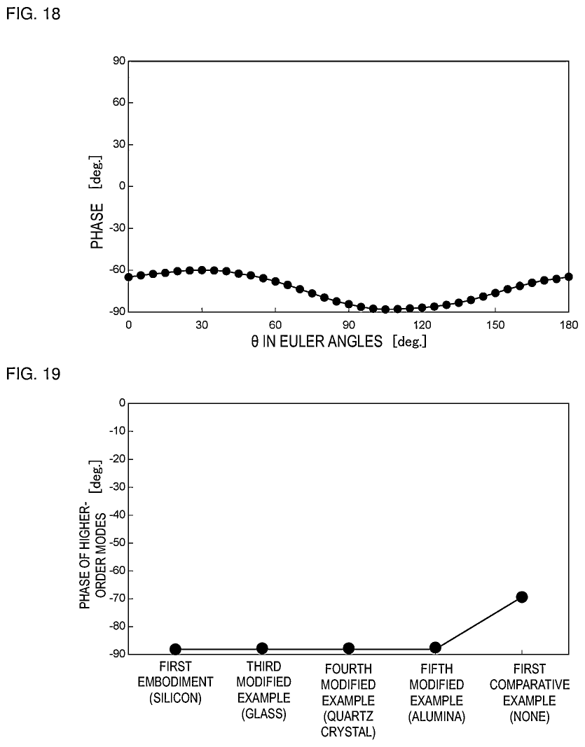

FIG. 18 is a diagram illustrating a relationship between θ in the Euler angles of the piezoelectric layer and the phase of the higher-order modes in the second modified example of the first preferred embodiment.

As illustrated in FIG. 18, in the second modified example of the first preferred embodiment, it is understood that the higher-order modes can be reduced or prevented regardless of θ in the Euler angles of the piezoelectric layer 6.

As described above, a material other than silicon may be used as the material for the support substrate 3. FIG. 19 illustrates phases of the higher-order modes in third to fifth modified examples in which only the material of the support substrate 3 is different from that of the first preferred embodiment. The higher-order modes illustrated in FIG. 19 is the higher-order modes around 7500 MHz. In the third modified example, the support substrate 3 is made of glass. In the fourth modified example, the support substrate 3 is made of a quartz crystal. In the fifth modified example, the support substrate 3 is made of alumina. FIG. 19 also illustrates the higher-order modes of the first comparative example. As described above, in the first comparative example, the portion of the piezoelectric layer 6 that overlaps the intersection region in plan view is not laminated on the support substrate 3.

FIG. 19 is a diagram illustrating the phases of the higher-order modes in the first preferred embodiment, the third to fifth modified example of the first preferred embodiment, and the first comparative example.

As illustrated in FIG. 19, it is understood that in all of the first preferred embodiment and the third to fifth modified examples of the first preferred embodiment, the higher-order modes are more reduced or prevented than in the first comparative example.

In the first preferred embodiment, the first IDT electrode 7A and the second IDT electrode 7B are made of Al, but are not limited thereto. Here, an acoustic velocity in the main mode was simulated by using different materials for the first IDT electrode 7A and the second IDT electrode 7B. Note that the main mode in the first preferred embodiment is a surface wave in the SH mode. In the following description, when the material of the first IDT electrode 7A is M1 and the material of the second IDT electrode 7B is M2, they are described as M1/M2. The combination of materials of the IDT electrode was four combinations of Al/Al, Al/Pt, Pt/Al, and Pt/Pt. In the simulation, the thicknesses of the first IDT electrode 7A and the second IDT electrode 7B were set to 0.07λ in each case.

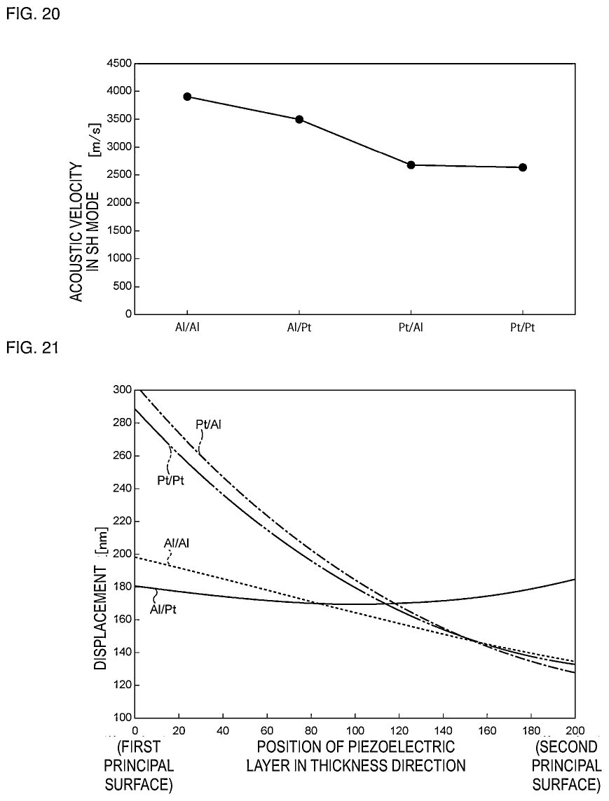

FIG. 20 is a diagram illustrating a relationship between a combination of materials of the first IDT electrode and the second IDT electrode and the acoustic velocity in the main mode.

As illustrated in FIG. 20, when at least one of the first IDT electrode 7A and the second IDT electrode 7B is made of Pt, the acoustic velocity in the main mode is lower than that in the case of Al/Al. When the acoustic velocity is low, the acoustic wave device 1 can be made smaller. More specifically, when a frequency is f and an acoustic velocity is v, an equation of f=v/λ is satisfied. To obtain a desired frequency f in the acoustic wave device 1, the lower the acoustic velocity v is, the shorter the wavelength λ is. As described above, the wavelength λ is determined by the electrode finger pitch. Thus, as the wavelength λ becomes shorter, the electrode finger pitch becomes narrower. Therefore, the IDT electrode can be made smaller. As described above, it is preferable that at least one of the first IDT electrode 7A and the second IDT electrode 7B be made of Pt. Thus, the first IDT electrode 7A and the second IDT electrode 7B can be reduced in size and the miniaturization of the acoustic wave device 1 can be advanced.

Further, the acoustic velocity in the main mode is lower in the case of Pt/Al and the case of Pt/Pt than in the case of Al/Pt. Therefore, the first IDT electrode 7A is preferably made of Pt. As a result, the miniaturization of the acoustic wave device 1 can be further advanced.

Under the same conditions as in the simulation related to the acoustic velocity in the SH mode, simulation related to the magnitude of displacement in the piezoelectric layer 6 was performed. Specifically, the simulation related to a relationship between a position of the piezoelectric layer 6 in the thickness direction and the magnitude of displacement was performed.

FIG. 21 is a diagram illustrating the displacement in the piezoelectric layer for each combination of materials of the first IDT electrode and the second IDT electrode. The position of the first principal surface 6a of the piezoelectric layer 6 is indicated by 0 on the horizontal axis of FIG. 21. The position of the second principal surface 6b is indicated by 200 on the horizontal axis.

As illustrated in FIG. 21, it is understood that the displacement when the horizontal axis is 0 is smaller in the case of Al/Al and the case of Al/Pt than in the case of Pt/Al and the case of Pt/Pt. That is, when the first IDT electrode 7A is made of Al, the displacement of the first principal surface 6a of the piezoelectric layer 6 can be reduced. Therefore, stresses applied to the first IDT electrode 7A can be reduced, and stress migration can be reduced or prevented. Accordingly, the first IDT electrode 7A is preferably made of Al. As a result, the stress migration can be reduced or prevented, and deterioration of electric power handling capability caused by the stress migration can be reduced or prevented.

The difference between a maximum value and a minimum value of the displacement in the piezoelectric layer 6 was calculated for each combination of the materials of the IDT electrode described above.

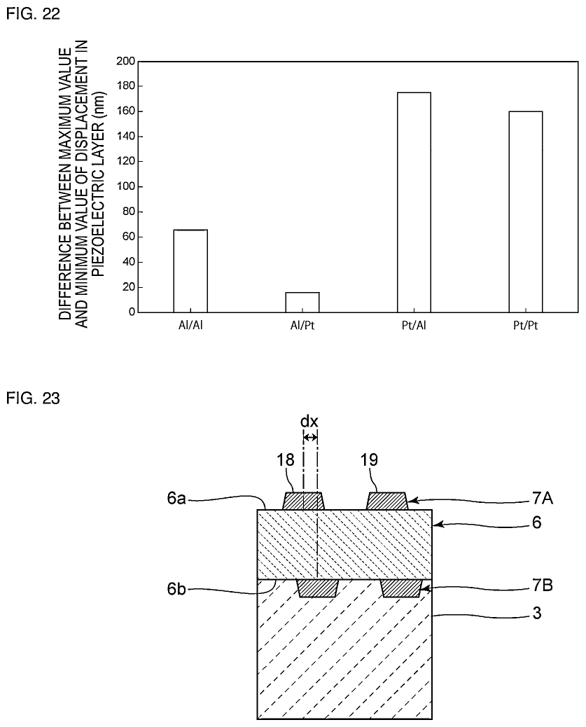

FIG. 22 is a diagram illustrating a relationship between a combination of materials of the first IDT electrode and the second IDT electrode and a difference between the maximum value and the minimum value of the displacement in the piezoelectric layer.

As illustrated in FIG. 22, it is understood that the difference between the maximum value and the minimum value of the displacement is the smallest in Al/Pt. Therefore, it is preferable that the first IDT electrode 7A be made of Al and the second IDT electrode 7B be made of Pt. In this case, the uniformity of displacement in the thickness direction of the piezoelectric layer 6 can be increased. As a result, the acoustic wave can be uniformly propagated in the thickness direction of the piezoelectric layer 6, and thus good electrical characteristics can be obtained. In addition, since the symmetry of the acoustic wave propagating in the thickness direction described above can be enhanced, the electrical characteristics can be stabilized against changes in the configuration of the acoustic wave device 1.

Note that, not limited to the case of Al/Pt, it is preferable that density of the second IDT electrode 7B be higher than density of the first IDT electrode 7A. Also in this case, good electrical characteristics can be obtained, and the electrical characteristics can be stabilized. When the second IDT electrode 7B is made of Pt, electrical resistance of the electrode fingers may increase in some cases. In this case, the second IDT electrode 7B may have a laminated structure including an Al layer and a Pt layer to reduce the electrical resistance.

Further, a relationship between the materials, densities, and thicknesses of the first IDT electrode 7A and the second IDT electrode 7B and a fractional bandwidth of the main mode was obtained. Note that, in the first preferred embodiment, the main mode is the SH mode. The thickness of the first IDT electrode 7A is represented by IDTu [λ], the thickness of the second IDT electrode 7B is represented by IDTd [λ], the density of the first IDT electrode 7A is represented by ρ1 [g/cm³], the density of the second IDT electrode 7B is represented by ρ2 [g/cm³], and the fractional bandwidth of the SH mode is represented by SH_BW [%].

Note that, in a case where the IDT electrode is a multilayer body of a plurality of electrode layers, when the thicknesses of the respective electrode layers are represented by t₁, t₂, . . . , and tₙ, an equation of IDTu (IDTd)=Σtₙ is satisfied. In addition, in this case, when the densities of the respective electrode layers are represented by ρ₁, ρ₂, . . . , and ρₙ, the density of the IDT electrode is Σ(ρₙ×tₙ)/Σtₙ. Further, in a case where the electrode layers are made of alloys, when the respective densities of elements of the alloys are represented by ρ₁, ρ₂, . . . , and ρₙ and the respective concentrations are p₁, p₂, . . . , and pₙ [%], an equation of density=Σ(ρₙ×pₙ) is satisfied.

Equation 1, which is a relational expression between IDTu, IDTd, ρ1, and ρ2 and SH_BW, was derived by simulation.

$$SH\_BW [ \% ] = 4.94288347869583 - 1.37989369528872 \times ( ID Td [ λ ] \times ρ2 [ g / {cm}^{3} ] ) + 1. 813184606833 \times ( IDTu [ λ ] \times ρ1 [ g / {cm}^{3} ] ) + 2.5 1396812128047 \times {( IDTd [ λ ] \times ρ2 [ g / {cm}^{3} ] )}^{2} - 2.282382053 \; 52906 \times {( IDTd [ λ ] \times ρ2 [ g / {cm}^{3} ] )}^{3} + 0.61094393501087 \times {( IDT d [ λ ] \times ρ2 [ g / {cm}^{3} ] )}^{4} - 22. 6347858439936 \times {( IDTu [ λ ] \times ρ1 [ g / {cm}^{3} ] )}^{2} + 63.8632598480415 \times {( IDTu [ λ ] \times ρ 1 [ g / {cm}^{3} ] )}^{3} - 74.1181743703044 \times {( IDTu [ λ ] \times ρ1 [ g / {cm}^{3} ] )}^{4} + 37.9952058002712 \times {( IDTu [ λ ] \times ρ1 [ g / {cm}^{3} ] )}^{5} - 7.14595960324194 \times {( IDTu [ λ ] \times ρ1 [ g / {cm}^{3} ] )}^{6} + 0.588480822096255 \times ( IDTd [ λ ] \times ρ2 [ g / {cm}^{3} ] ) \times ( IDTu [ λ ] \times ρ1 [ g / {cm}^{3} ] ) \qquad Equation 1$$

IDTu, IDTd, ρ1, and ρ2 are preferably thicknesses and densities within a range in which SH_BW derived from Equation 1 is equal to or more than about 3%, for example. In this case, the acoustic wave device 1 can be suitably used in a filter device. IDTu, IDTd, ρ1, and ρ2 are more preferably thicknesses and densities within a range in which SH_BW derived from Equation 1 is equal to or more than about 3.5%, for example, further preferably thicknesses and densities within in a range in which SH_BW derived from Equation 1 is equal to or more than about 4%, for example. Thus, when the acoustic wave device 1 is used in a filter device, insertion loss can be reduced. IDTu, IDTd, ρ1, and ρ2 are still further preferably thicknesses and densities within a range in which SH_BW derived from Equation 1 is equal to or more than about 4.5%, for example. As a result, insertion loss can be further reduced, and it is easy to comply with the next-generation communication standards.

As the values of ρ1 and ρ2 in Equation 1, for example, the following densities of metals [g/cm³] may be used. Al: about 2.699, Cu: about 8.96, Ag: about 10.05, Au: about 19.32, Pt: about 21.4, W: about 19.3, Ti: about 4.54, Ni: about 8.9, Cr: about 7.19, Mo: about 10.28. In this case, in the first IDT electrode 7A and the second IDT electrode 7B that are made of metals corresponding to the densities used as ρ1 and ρ2, IDTu and IDTd preferably have thicknesses within a range in which SH_BW derived from Equation 1 is equal to or more than about 3%, for example. In the above case, the range of the thicknesses of IDTu and IDTd is more preferably within a range in which SH_BW derived from Equation 1 is equal to or more than about 3.5%, further preferably within a range in which SH_BW is equal to or more than about 4%, and still further preferably within a range in which SH_BW derived from Equation 1 is equal to or more than about 4.5%, for example.

On the other hand, when the first IDT electrode 7A is the multilayer body of a plurality of electrode layers made of metals selected from the group of metals described above, the density calculated from Σ(ρₙ×tₙ)/Σtₙ may be used as ρ1 in Equation 1. In contrast, when the electrode layers of the first IDT electrode 7A are alloyed layers made of two or more metals selected from the group of metals described above, the density obtained from Σ(ρₙ×pₙ) may be used as ρ1 in Equation 1. When the first IDT electrode 7A is a multilayer body of alloyed layers, Σ(ρₙ×tₙ)/Σtₙ and Σ(ρₙ×pₙ) may be used together. The same applies to the case where the second IDT electrode 7B is a multilayer body of a plurality of electrode layers or the case where the electrode layer of the second IDT electrode 7B is an alloyed layer.

In contrast, a relationship between the duty ratios of the first IDT electrode 7A and the second IDT electrode 7B and the fractional bandwidth of the SH mode was obtained. The duty ratio of the first IDT electrode 7A is defined as duty_u, and the duty ratio of the second IDT electrode 7B is defined as duty_d. Equation 2, which is a relational expression between duty_u and duty_d and SH_BW, was derived by simulation.

$$SH\_BW [ \% ] = 4.82 3495779 \; 98388 - 3.6 1425920727 \; 189 \times duty\_u - 1.56118181746504 \times duty\_d + 13. 38304114090 \; 58 \times {duty\_u}^{2} - 12. 0 \; 401956788195 \times {duty\_u}^{3} + 6.29516073499509 \times {duty\_d}^{2} - 8.10795949927642 \times {duty\_d}^{3} \qquad Equation 2$$

The duty ratios of duty_u and duty_d are preferably within a range in which SH_BW derived from Equation 2 is equal to or more than about 4%, and more preferably within a range in which SH_BW derived from Equation 2 is equal to or more than about 4.5%, for example. Thus, when the acoustic wave device 1 is used in a filter device, insertion loss can be reduced.

On the other hand, Equation 3, which is a relational expression between duty_u and duty_d and the phase of an unnecessary wave, is derived by simulation. Note that, due to the unnecessary wave, ripples may occur on a frequency side higher than an anti-resonant frequency.

Phase of unnecessary wave[deg.]=69.4+162.7×duty_d−136.7×duty_u−179.6×duty_d²−108.2×duty_u²+164.2×duty_d×duty_u Equation 3

It is preferable that duty_u and duty_d be duty ratios in a range in which the phase of the unnecessary wave derived from Equation 3 are equal to or less than about −30 deg. As a result, the ripples that occur on a frequency side higher than the anti-resonant frequency can be reduced or prevented.

In the first preferred embodiment, the center of the plurality of electrode fingers in the intersection region A of the first IDT electrode 7A and the center of the plurality of electrode fingers in the intersection region of the second IDT electrode 7B overlap each other in plan view. However, as illustrated in FIG. 23, the centers of the plurality of electrode fingers of the first IDT electrode 7A and the second IDT electrode 7B do not necessarily overlap each other.

A distance between the centers of the first IDT electrode 7A and the second IDT electrode 7B in the acoustic wave propagation direction when viewed in plan view is defined as dx [λ]. A relationship between dx, and the resonant frequency, the anti-resonant frequency, and the fractional bandwidth was obtained by simulation. Design parameters of the acoustic wave device 1 are as follows. Note that, in the first IDT electrode 7A and the second IDT electrode 7B, the electrode fingers overlapping each other in plan view have the same potential. That is, when dx=0, the first IDT electrode 7A and the second IDT electrode 7B facing each other have the same potential. When dx=0.5, the potentials of the first IDT electrode 7A and the second IDT electrode 7B are in opposite phases.
Support substrate 3; material: Si, plane orientation: (100) plane
Piezoelectric layer 6; material: LiTaO₃, cut-angles: 30° Y-cut X-propagation, thickness: 0.2λ
Orientation relationship between the support substrate 3 and the piezoelectric layer 6; the Si [110] direction and the X_{Li} axis direction are parallel to each other.
First IDT electrode 7A; material: Al, thickness: 0.07λ, duty ratio: 0.5
Second IDT electrode 7B; material: Al, thickness: 0.07λ, duty ratio: 0.5
Wavelength λ: 1 μm
dx; varied in increments of 0.01λ within a range being equal to or more than 0λ and equal to or less than 0.5λ.

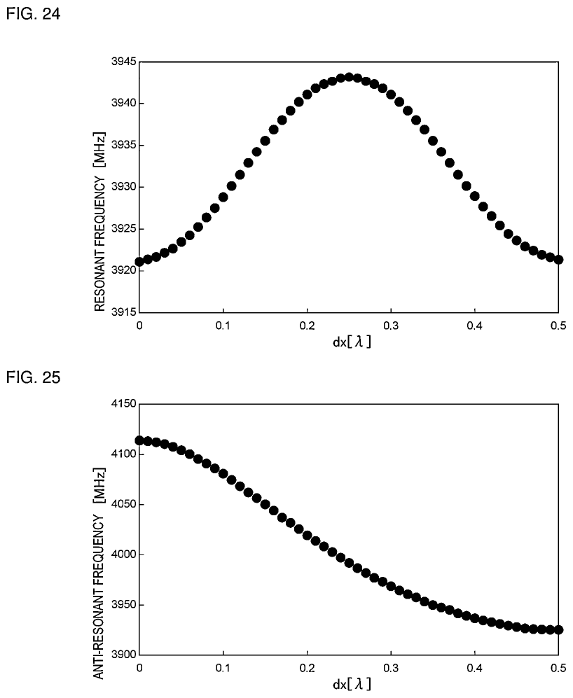

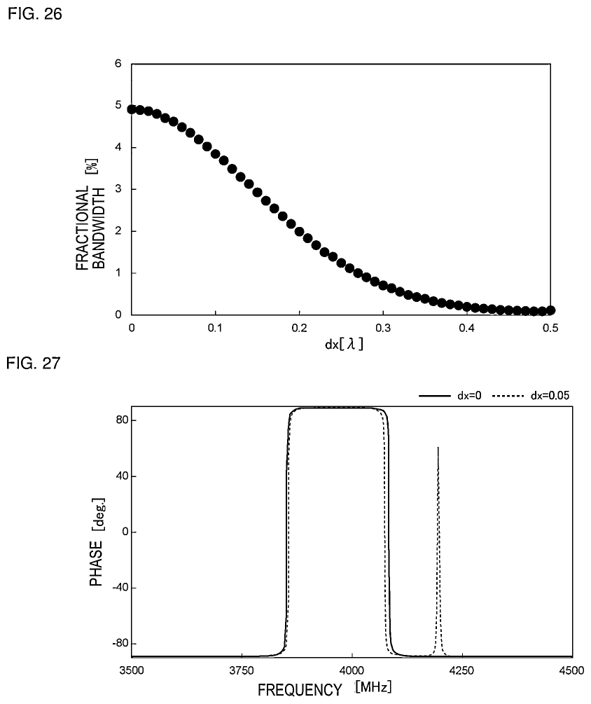

FIG. 24 is a diagram illustrating a relationship between a distance dx and the resonant frequency. FIG. 25 is a diagram illustrating a relationship between the distance dx and the anti-resonant frequency. FIG. 26 is a diagram illustrating a relationship between the distance dx and the fractional bandwidth.

As illustrated in FIG. 24, the resonant frequency is the highest when the distance dx is about 0.25λ, for example. Note that when the distance dx is equal to or more than 0λ and equal to or less than about 0.25λ, the resonant frequency becomes higher as the distance dx becomes longer, and when the distance dx is equal to or more than about 0.25λ and equal to or less than about 0.5λ, the resonant frequency becomes lower as the distance dx becomes longer. Therefore, the resonant frequency can be adjusted by adjusting the distance dx. More specifically, in a case where the resonant frequency is increased by equal to or more than about 0.1% as compared with a case where dx is 0λ, it is sufficient that about 0.07λ≤dx≤ about 0.43λ is satisfied. In a case where the resonant frequency is increased by equal to or more than about 0.2%, it is sufficient that about 0.1λ≤dx≤ about 0.4λ is satisfied. In a case where the resonant frequency is increased by equal to or more than about 0.3%, it is sufficient that about 0.13λ≤dx≤ about 0.37λ is satisfied, for example. In a case where the resonant frequency is increased by equal to or more than about 0.4%, it is sufficient that about 0.16λ≤dx≤ about 0.34λ is satisfied, for example. In a case where the resonant frequency is increased by equal to or more than about 0.5%, it is sufficient that about 0.2λ≤dx≤ about 0.3λ is satisfied, for example.

On the other hand, as illustrated in FIG. 25, it is understood that the longer the distance dx, the lower the anti-resonant frequency. As illustrated in FIG. 26, it is understood that the longer the distance dx is, the smaller the value of the fractional bandwidth is. Thus, the fractional bandwidth can be adjusted by adjusting the distance dx. More specifically, in a case where the fractional bandwidth is to be equal to or more than about 4% and equal to or less than about 5%, it is sufficient that about 0λ≤dx≤ about 0.09λ is satisfied. In a case where the fractional bandwidth is to be equal to or more than about 3% and equal to or less than about 4%, it is sufficient that about 0.09λ≤dx≤ about 0.15λ is satisfied, for example. In a case where the fractional bandwidth is to be equal to or more than about 2% and equal to or less than about 3%, it is sufficient that about 0.15λ≤dx≤ about 0.2λ is satisfied, for example. In a case where the fractional bandwidth is to be equal to or more than about 1% and equal to or less than about 2%, it is sufficient that about 0.2λ≤dx≤ about 0.27λ is satisfied, for example. In a case where the fractional bandwidth is to be equal to or more than about 0% and equal to or less than about 1%, it is sufficient that about 0.27λ≤dx≤ about 0.5λ is satisfied, for example. When the acoustic wave device 1 is used in a filter device, the fractional bandwidth required for each band of the filter device is different. In the present preferred embodiment, the fractional bandwidth can be easily adjusted for each band of the filter device to be used.

When the distance dx is other than 0λ, ripples due to an unnecessary wave occurs at a frequency higher than the anti-resonant frequency. The relationship between the distance dx and magnitude of the ripples was obtained by simulation.

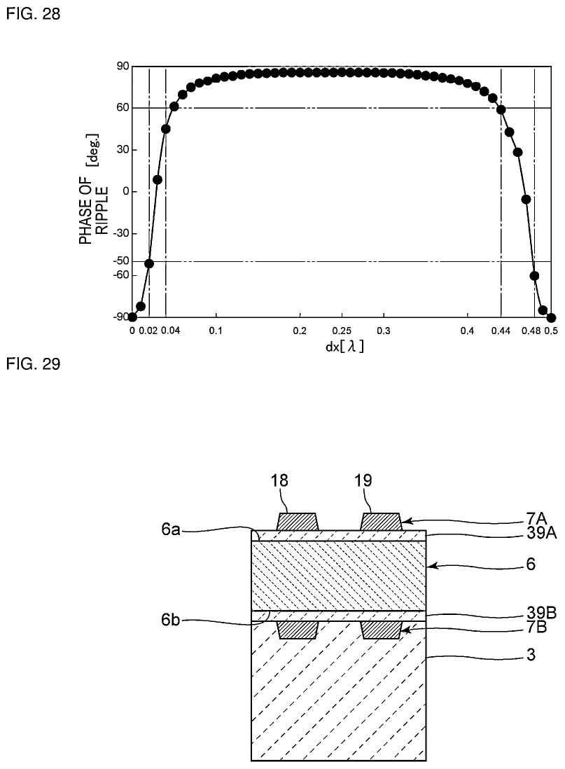

FIG. 27 is a diagram illustrating the phase characteristics when the distance dx is 0λ and when the distance dx is about 0.05λ, for example. FIG. 28 is a diagram illustrating a relationship between the distance dx and the phase of the unnecessary wave that becomes the ripples.

As illustrated in FIG. 27, it is understood that ripples occur on the frequency side higher than the anti-resonant frequency. As illustrated in FIG. 28, when the distance dx is equal to or more than 0λ and equal to or less than about 0.25λ, the ripples become larger as the distance dx becomes longer, and when the distance dx is equal to or more than about 0.25λ and equal to or less than about 0.5λ, for example, the ripples become smaller as the distance dx becomes longer. It is preferable that the distance dx be about 0λ≤dx≤ about 0.04λ or about 0.44λ≤dx≤ about 0.5λ, for example. Thus, the ripples can be reduced or prevented to be equal to or less than about 60 deg. It is preferable that the distance dx be about 0λ≤dx≤ about 0.02λ or about 0.48λ≤dx≤ about 0.5λ, for example. As a result, the ripples can be reduced or prevented to be equal to or less than about −50 deg, for example.

Here, a direction in which the plurality of first electrode fingers 18 and the plurality of second electrode fingers 19 extend is an electrode finger extending direction. In the present preferred embodiment, the electrode finger extending direction is orthogonal to the acoustic wave propagation direction. The distance in the electrode finger extending direction between the centers of the intersection regions of the first IDT electrode 7A and the second IDT electrode 7B is represented by dy [λ]. In the range of about 0λ≤dy≤ about 0.5λ, for example, a relationship between the distance dy, the resonant frequency, the anti-resonant frequency, and the fractional bandwidth was obtained by simulation. As a result, it was confirmed that the influence of the distance dy on the resonant frequency, the anti-resonant frequency, and the fractional bandwidth was slight. Thus, the distance dy may be, for example, within a range of about 0λ≤dy≤ about 0.5λ. Alternatively, both the distance dx and the distance dy may be other than 0λ.

FIG. 29 is a schematic elevational cross-sectional view illustrating the vicinity of a pair of electrode fingers of each of a first IDT electrode and a second IDT electrode in an acoustic wave device according to a second preferred embodiment of the present invention.

The present preferred embodiment is different from the first preferred embodiment in that an insulation layer 39A is provided between a first IDT electrode 7A and a piezoelectric layer 6. The present preferred embodiment is also different from the first preferred embodiment in that an insulation layer 39B is provided between second IDT electrode 7B and the piezoelectric layer 6. Except for the above points, the acoustic wave device of the present preferred embodiment has the same configuration as that of the acoustic wave device 1 of the first preferred embodiment.

To be specific, the insulation layer 39A and the insulation layer 39B are silicon nitride layers. However, the material of the insulation layer 39A and the insulation layer 39B is not limited to the above, for example, silicone oxide, tantalum oxide, alumina, silicone oxynitride, or the like can also be used. The fractional bandwidth can be adjusted easily by adjusting the thicknesses of the insulation layer 39A and the insulation layer 39B.

Also in the present preferred embodiment, same as the first preferred embodiment, the piezoelectric layer 6 is supported by a support substrate 3 also in a portion where an acoustic wave is excited. Therefore, fluctuations in the electrical characteristics due to a change in the shape of the piezoelectric layer 6 can be reduced or prevented. Further, since the higher-order modes can be leaked to the support substrate 3 side, the higher-order modes can be reduced or prevented.

It is sufficient that an insulation layer may be provided between at least one of the first IDT electrode 7A and the second IDT electrode 7B and the piezoelectric layer 6. Hereinafter, it will be described that the higher-order modes can be reduced or prevented even when an arrangement of the insulation layers is changed. The effects described above will be described by comparing the second preferred embodiment, the first modified example thereof, and the second modified example thereof with the second comparative example. In the first modified example, the insulation layer 39A is provided between the first IDT electrode 7A and the piezoelectric layer 6. On the other hand, the insulation layer 39B is not provided. In the second modified example, the insulation layer 39B is provided between the second IDT electrode 7B and the piezoelectric layer 6. In contrast, the insulation layer 39A is not provided. In the second comparative example, the insulation layer is not provided. In addition, in the second comparative example, a portion of the piezoelectric layer that overlaps an intersection region in plan view is not laminated on the support substrate.

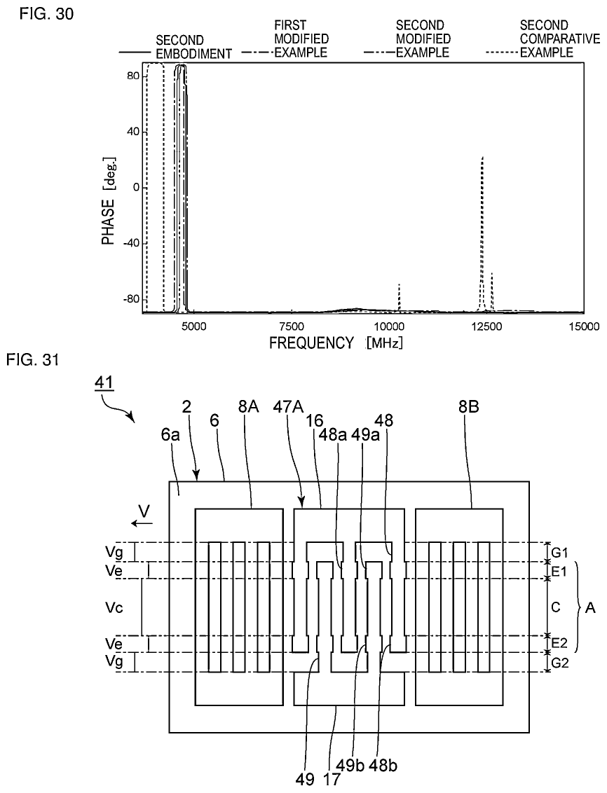

FIG. 30 is a diagram illustrating the phase characteristics in the second preferred embodiment, the first modified example thereof, the second modified example thereof, and the second comparative example.

As illustrated in FIG. 30, in the second comparative example, a plurality of higher-order modes is generated. On the other hand, in the second preferred embodiment, the first modified example thereof and the second modified example thereof, it is understood that the higher-order modes are reduced or prevented. FIG. 30 illustrates the results when the insulation layer 39A is about 0.01λ thick and the insulation layer 39B is about 0.01 λ thick, for example. However, it is known that the higher-order modes can be similarly reduced or prevented even when the thicknesses of the insulation layer 39A and the insulation layer 39B are changed.

FIG. 31 is a schematic plan view illustrating a configuration of a first IDT electrode according to a third preferred embodiment of the present invention.

The present preferred embodiment is different from the first preferred embodiment in that an acoustic wave device 41 uses a piston mode. Except for the above point, the acoustic wave device 41 of the present preferred embodiment has the same configuration as that of the acoustic wave device 1 of the first preferred embodiment.

Specifically, an intersection region A of a first IDT electrode 47A includes a central region C and a pair of edge regions. The pair of edge regions is a first edge region E1 and a second edge region E2. The central region C is a region located on a central side in an electrode finger extending direction. The first edge region E1 and the second edge region E2 face each other with the central region C in between in the electrode finger extending direction. Further, the first IDT electrode 47A includes a pair of gap regions. The pair of gap regions are a first gap region G1 and a second gap region G2. The first gap region G1 is located between a first busbar 16 and the intersection region A. The second gap region G2 is located between a second busbar 17 and the intersection region A.

A plurality of first electrode fingers 48 each includes a wide portion 48a located in the first edge region E1 and a wide portion 48b located in the second edge region E2. In each of the electrode fingers, the width of the wide portion is wider than the width of the other portions. Similarly, a plurality of second electrode fingers 49 each includes a wide portion 49a located in the first edge region E1 and a wide portion 49b located in the second edge region E2. Note that the width of the electrode finger is a dimension of the electrode finger along the acoustic wave propagation direction.

In the first IDT electrode 47A, since the wide portion 48a and the wide portion 49a described above are provided, an acoustic velocity in the first edge region E1 is lower than an acoustic velocity in the central region C. Further, since the wide portion 48b and the wide portion 49b are provided, an acoustic velocity in the second edge region E2 is lower than the acoustic velocity in the central region C. That is, a pair of low acoustic velocity regions is provided in the pair of edge regions. The low acoustic velocity region is a region in which the acoustic velocity is lower than the acoustic velocity in the central region C.

In contrast, in the first gap region G1, only the plurality of first electrode fingers 48 are provided, of the plurality of first electrode fingers 48 and the plurality of second electrode fingers 49. In the second gap region G2, only the plurality of second electrode fingers 49 are provided, of the plurality of first electrode fingers 48 and the plurality of second electrode fingers 49. Thus, the acoustic velocities in the first gap region G1 and the second gap region G2 are higher than the acoustic velocity in the central region C. That is, a pair of high acoustic velocity regions is provided in the pair of gap regions. The high acoustic velocity region is a region in which an acoustic velocity is higher than the acoustic velocity in the central region C.

Here, when the acoustic velocity in the central region C is represented by Vc, the acoustic velocity in the first edge region E1 and the second edge region E2 is represented by Ve, and the acoustic velocity in the first gap region G1 and the second gap region G2 is represented by Vg, the relationship between the acoustic velocities is Vg>Vc>Ve. Note that, in the portion in FIG. 31 indicating the relationship between the acoustic velocities, as indicated by an arrow V, the acoustic velocity increases as the line indicating the height of each acoustic velocity is located further on the left side. From the center of the electrode finger extending direction, the central region C, the pair of low acoustic velocity regions, and the pair of high acoustic velocity regions are arranged in this order. Accordingly, the piston mode is established. As a result, a transverse mode can be reduced or prevented.

Note that at least one electrode finger of the plurality of first electrode fingers 48 and the plurality of second electrode fingers 49 may have a wide portion in at least one of the first edge region E1 and the second edge region E2. However, it is preferable that all the first electrode fingers 48 have the wide portion 48a and the wide portion 48b in both edge regions and all the second electrode fingers 49 have the wide portion 49a and the wide portion 49b in both edge regions.

In the present preferred embodiment, the second IDT electrode is also configured in the same manner as the first IDT electrode 47A. That is, in the second IDT electrode, the plurality of first electrode fingers and the plurality of second electrode fingers have wide portions located in both edge regions. However, it is sufficient that the low acoustic velocity region is provided in at least one of the first edge region and the second edge region in at least one of the first IDT electrode 47A and the second IDT electrode. When the wide portions are provided in both the first IDT electrode 47A and the second IDT electrode, the acoustic velocity can be further reduced, and thus the effect of reducing or preventing the transverse mode is improved.

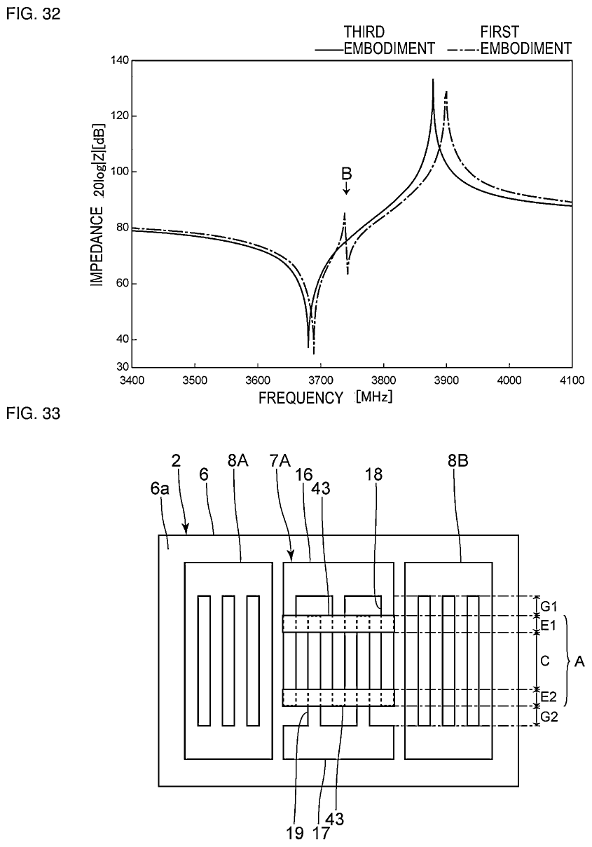

FIG. 32 is a diagram illustrating impedance-frequency characteristics of the first preferred embodiment and the third preferred embodiment.

As indicated by an arrow B in FIG. 32, the transverse mode occurs in the first preferred embodiment. In the third preferred embodiment, since the piston mode is used, it is understood that the transverse mode can be reduced or prevented. Therefore, when reducing or preventing of the transverse mode is necessary, the third preferred embodiment may be applied. Further, it is understood that the impedance at the anti-resonant frequency can be increased in the third preferred embodiment. This is a specific effect due to the fact that the first IDT electrode 47A and the second IDT electrode face each other with the piezoelectric layer 6 in between, the second IDT electrode is embedded in the support, and the piston mode is used.

By providing a mass addition film, the transverse mode can also be reduced or prevented. In the first modified example of the third preferred embodiment illustrated in FIG. 33, a mass addition film 43 is provided in each of the pair of edge regions. The mass addition films 43 has a belt-like shape. The mass addition films 43 is provided over the plurality of electrode fingers. The mass addition films 43 is also provided in a portion between the electrode fingers on the piezoelectric layer 6. Note that the mass addition films 43 may be provided between the plurality of electrode fingers and the piezoelectric layer 6. The mass addition films 43 may overlap the plurality of electrode fingers in plan view. Alternatively, a plurality of mass addition films may be provided, and the mass addition films may overlap the respective electrode fingers in plan view. Thus, a pair of low acoustic velocity regions can be provided in the pair of edge regions. The mass addition film 43 may be provided on at least one of a first principal surface 6a side and a second principal surface 6b side of the piezoelectric layer 6.

Alternatively, for example, the thickness of the plurality of electrode fingers in the pair of edge regions may be thicker than the thickness in the central region. Also in this case, the pair of low acoustic velocity regions can be provided in the pair of edge regions. Alternatively, for example, the first IDT electrode or the second IDT electrode may have a configuration in which a cavity is provided in the busbar and the piston mode is used, as described in International Publication No. 2016/084526. In any of the above-described cases, as in the third preferred embodiment, it is possible to reduce or prevent fluctuations in the electrical characteristics due to a change in the shape of the piezoelectric layer and to reduce or prevent the higher-order modes and the transverse mode.

The transverse mode can also be reduced or prevented by an IDT electrode with a configuration not using the piston mode. A second modified example and a third modified example of the third preferred embodiment which are different from the third preferred embodiment only in the configuration of the first IDT electrode and the second IDT electrode will be described below. In each of the second modified example and the third modified example, the first IDT electrode has the same configuration as that of the second IDT electrode. Also, in the second modified example and the third modified example, same as the third preferred embodiment, it is possible to reduce or prevent fluctuations in the electrical characteristics due to a change in the shape of the piezoelectric layer, and to reduce or prevent the higher-order modes and the transverse mode.

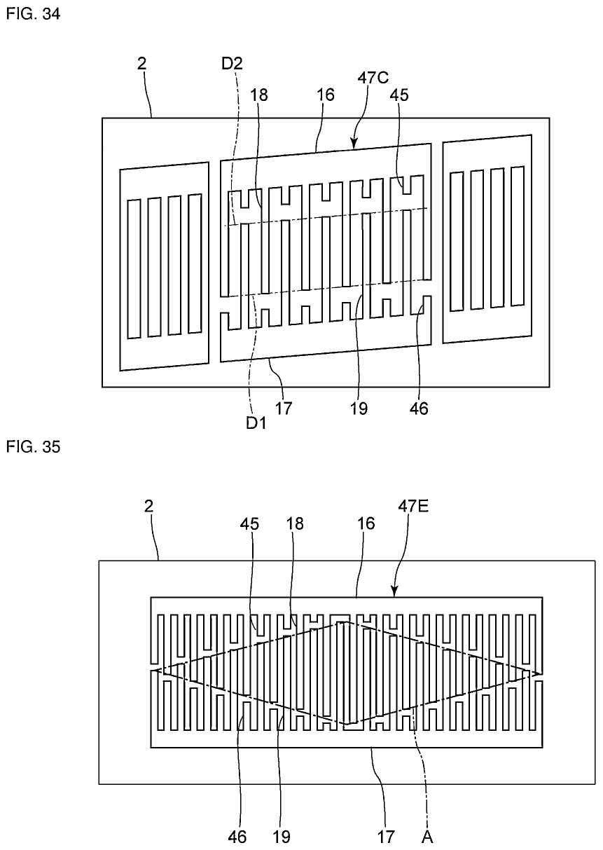

In the second modified example illustrated in FIG. 34, a first IDT electrode 47C is an inclined IDT electrode. To be more specific, when a virtual line defined by connecting the tips of a plurality of first electrode fingers 18 is defined as a first envelope D1, the first envelope D1 is inclined with respect to the acoustic wave propagation direction. Similarly, when a virtual line defined by connecting the tips of a plurality of second electrode fingers 19 is defined as a second envelope D2, the second envelope D2 is inclined with respect to the acoustic wave propagation direction. The envelopes do not have to be parallel to each other but are preferably parallel to each other because the transverse mode suppression capability is higher.

The first IDT electrode 47C includes a plurality of first dummy electrode fingers 45 and a plurality of second dummy electrode fingers 46. One end of each of the plurality of first dummy electrode fingers 45 is connected to the first busbar 16. The other end of each of the plurality of first dummy electrode fingers 45 faces each of the plurality of second electrode fingers 19 with a gap in between. One end of each of the plurality of second dummy electrode fingers 46 is connected to the second busbar 17. The other end of each of the plurality of second dummy electrode fingers 46 faces each of the plurality of first electrode fingers 18 with a gap in between. However, the plurality of first dummy electrode fingers 45 and the plurality of second dummy electrode fingers 46 do not have to be provided.

In the third modified example illustrated in FIG. 35, a first IDT electrode 47E is an apodized IDT electrode. To be more specific, when a dimension of the intersection region A along the electrode finger extending direction is referred to as an intersecting width, the intersecting width of the first IDT electrode 47E varies in the acoustic wave propagation direction. The intersecting width decreases from the center of the first IDT electrode 47E in the acoustic wave propagation direction toward an outer side portion. The intersection region A has a substantially rhombic shape in plan view. However, the shape of the intersection region A in plan view is not limited to the above shape.

Also in the present modified example, a plurality of dummy electrode fingers is provided. The lengths of the plurality of dummy electrode fingers are different from each other and lengths of the plurality of electrode fingers are different from each other. Thus, the intersecting width changes as described above. The lengths of the dummy electrode fingers and the lengths of the electrode fingers have dimensions that extend along the electrode finger extending direction of the dummy electrode fingers and the electrode fingers. Note that, in FIG. 35, the reflector is omitted.

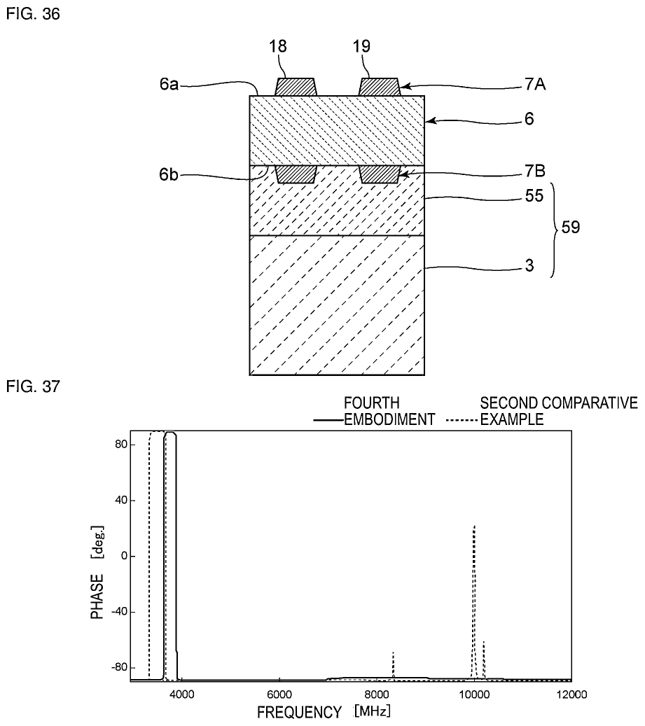

FIG. 36 is a schematic elevational cross-sectional view illustrating the vicinity of a pair of electrode fingers of each of a first IDT electrode and a second IDT electrode in an acoustic wave device according to a fourth preferred embodiment of the present invention.

The present preferred embodiment is different from the first preferred embodiment in that a support 59 includes a dielectric layer 55. The dielectric layer 55 is provided between a support substrate 3 and a piezoelectric layer 6. The dielectric layer 55 is directly laminated on the piezoelectric layer 6. Thus, a second IDT electrode 7B is embedded in the dielectric layer 55. Except for the above points, the acoustic wave device of the present preferred embodiment has the same configuration as that of the acoustic wave device 1 of the first preferred embodiment.

The dielectric layer 55 is a silicon oxide layer. However, the material of the dielectric layer 55 is not limited to the above, for example, silicon oxynitride, lithium oxide, tantalum pentoxide, or the like may be used.

In the present preferred embodiment, same as the first preferred embodiment, the piezoelectric layer 6 is supported by the support 59 also in a portion where an acoustic wave is excited. Therefore, fluctuations in the electrical characteristics due to a change in the shape of the piezoelectric layer 6 can be reduced or prevented. Further, since the higher-order modes can be leaked to a support 59 side, the higher-order modes can be reduced or prevented.

In the fourth preferred embodiment, the phase characteristics were obtained by performing simulation. Design parameters of the acoustic wave device were as follows. Note that a thickness of the dielectric layer 55 is a distance between layers adjacent to the dielectric layer 55. To be more specific, in the present preferred embodiment, the thickness of the dielectric layer 55 is the distance between the support substrate 3 and the piezoelectric layer 6. FIG. 37 illustrates the phase characteristics together with the phase characteristics of the second comparative example. In the second comparative example, a portion of the piezoelectric layer overlapping the intersection region in plan view is not laminated with the support.
Support substrate 3; material: Si, plane orientation: (100) plane
Dielectric layer 55; material: SiO₂, thickness: 0.27λ
Piezoelectric layer 6; material: LiTaO₃, cut-angles: 30° Y-cut X-propagation, thickness: 0.2λ
Orientation relationship between the support substrate 3 and the piezoelectric layer 6; the Si [110] direction and the X_{Li} axis direction are parallel to each other.
First IDT electrode 7A; material: Al, thickness: 0.07λ, duty ratio: 0.5
Second IDT electrode 7B; material: Al, thickness: 0.07λ, duty ratio: 0.5
Wavelength λ: 1 μm

FIG. 37 is a diagram illustrating the phase characteristics in the fourth preferred embodiment and the second comparative example.

As illustrated in FIG. 37, a plurality of higher-order modes is generated in the second comparative example. In contrast, it is understood that the higher-order modes are reduced or prevented in the present preferred embodiment. Note that it is known that the higher-order modes are also reduced or prevented when the material and the thickness of the dielectric layer 55 are changed.

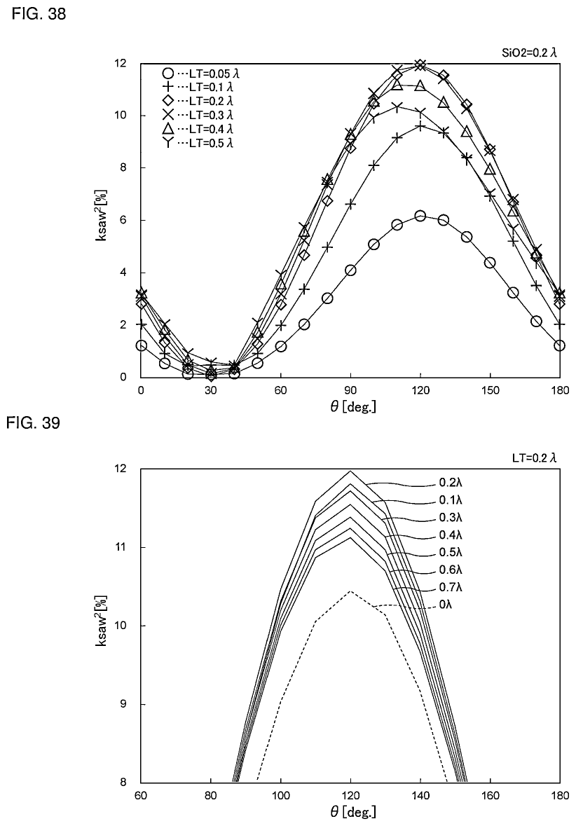

In the present preferred embodiment, the main mode is a surface wave of the SH mode. An electromechanical coupling coefficient ksaw² in the SH mode depends on θ in the Euler angles (φ, θ, ψ) and the thickness of the piezoelectric layer 6 and the thickness of the dielectric layer 55. This example is described with FIGS. 38 and 39.

Note that θ was varied in increments of about 10 deg. within a range being equal to or more than about 0 deg. and equal to or less than about 180 deg. The thickness of the piezoelectric layer 6 was varied in increments of about 0.05λ within a range being equal to or more than about 0.05λ and equal to or less than about 0.1λ, and in increments of about 0.1λ within a range being equal to or more than about 0.1λ and equal to or less than about 0.5λ. The thickness of the dielectric layer 55 was varied in increments of about 0.1λ within a range being equal to or more than about 0λ and equal to or less than about 1λ. However, when the thickness of the dielectric layer 55 is 0λ, the configuration is the same as that of the first preferred embodiment since the dielectric layer 55 is not provided. The electromechanical coupling coefficient ksaw² in the SH mode was obtained by simulation at each of the angles and the thicknesses described above.

FIG. 38 is a diagram illustrating a relationship between θ in the Euler angles and the thickness of the piezoelectric layer and the electromechanical coupling coefficient ksaw² in the SH mode in the fourth preferred embodiment. FIG. 39 is a diagram illustrating a relationship between the electromechanical coupling coefficient ksaw² in the SH mode and θ in the Euler angles of the piezoelectric layer and the thickness of the dielectric layer in the fourth preferred embodiment. The results illustrated in FIG. 38 are the results when the thickness of the dielectric layer 55 is about 0.2λ, for example. The results illustrated in FIG. 39 are the results when the thickness of the piezoelectric layer 6 is set to about 0.2λ, for example. Note that, in FIG. 38, the thickness of the dielectric layer 55 is represented by SiO2 [λ]. In FIGS. 38 and 39, the thickness of the piezoelectric layer 6 is represented by LT [λ].

As illustrated in FIGS. 38 and 39, it is understood that the electromechanical coupling coefficient ksaw² of the SH mode depends on θ in the Euler angles and the thickness of the piezoelectric layer 6 and the thickness of the dielectric layer 55. The thickness of the piezoelectric layer 6 is preferably equal to or more than about 0.05λ and equal to or less than about 0.5λ, for example. Thus, the electromechanical coupling coefficient ksaw² in the SH mode can be suitably adjusted. The thickness of the dielectric layer 55 is preferably more than about 0λ and equal to or less than about 0.5λ, for example. As a result, the electromechanical coupling coefficient ksaw² in the SH mode can be increased and can be suitably adjusted.

The thickness of the piezoelectric layer 6 is represented by LT [λ], the thickness of the dielectric layer 55 is represented by SiO2 [λ], θ in the Euler angles (φ, θ, ψ) of the piezoelectric layer 6 is represented by LT-θ [deg.], and the electromechanical coupling coefficient in the SH mode is represented by SH_ksaw² [%]. Equation 4, which is a relational expression between LT, SiO2, LT-θ, and SH_ksaw², was derived by simulation.

$${SH\_ksaw}^{2} [ \% ] = - 2.421 \; 876208 \; 28543 + 62.484281524666 \times ( LT [ λ ] ) - 0.107924507780421 \times ( LT - θ [ deg . ] ) + 8.90369850943586 \times ( SiO 2 [ λ ] ) - 268.852679355883 \times {( LT [ λ ] )}^{2} + 49 \; 9.449089766496 \times {( L T [ λ ] )}^{3} - 350.1068 \; 60593976 \times {( L T [ λ ] )}^{4} - 0.00180396948527691 \times {( LT - θ [ d e g . ] )}^{2} + 0.000124241019900316 \times {( LT - θ [ deg . ] )}^{3} - 0. 00001397072297 \; 5499 \times {( LT - θ [ deg . ] )}^{4} + 0.000000005862448 \; 4454 \times {( LT - θ [ deg . ] )}^{5} - 8.4861389677363 e - 12 \times {( LT - θ [ deg . ] )}^{6} - 38.0582687313641 \times {( SiO 2 [ λ ] )}^{2} + 71.3862412045158 \times {( SiO 2 [ λ ] )}^{3} - 62. 6002863635 \; 122 \times {( SiO2 [ λ ] )}^{4} + 20.7954101598776 \times {( SiO 2 [ λ ] )}^{5} + 0. 1751045811 \; 23753 \times ( LT [ λ ] ) \times ( LT - θ [ deg . ] ) \qquad Equation 4$$

LT, SiO2, and LT-θ are preferably thicknesses and an angle in a range in which SH_ksaw² derived from Equation 4 is equal to or more than about 6%, for example. Thus, the acoustic wave device can be suitably used in a filter device. LT, SiO2, and LT-θ are more preferably thicknesses and an angle in a range in which SH_ksaw² derived from Equation 4 is equal to or more than about 8%, and further preferably thicknesses and an angle in a range in which SH_ksaw² derived from Equation 4 is equal to or more than about 10%, for example. As a result, when the acoustic wave device is used in a filter device, insertion loss can be reduced.

When the SH mode is used, a Rayleigh mode becomes an unnecessary wave. The electromechanical coupling coefficient in the Rayleigh mode is represented by Rayleigh_ksaw² [%]. Equation 5, which is a relational expression between LT, SiO2, LT-θ, and Rayleigh_ksaw², was derived by simulation. Note that in the present specification, “e-a (a is an integer)” in an equation represents “×10^{-a}”.

$${Rayleigh\_ksaw}^{2} [ \% ] = ( - 0.986147947509026 ) - 4.80914444146841 \times ( LT [ λ ] ) + 0.0696242386883329 \times ( L T - θ [ d e g . ] ) + 1.19398580127017 \times ( SiO 2 [ λ ] ) + 103.399105364715 \times {( LT [ λ ] )}^{2} - 279.94327949742 \times {( LT [ λ ] )}^{3} + 227. 888456729838 \times {( L T [ λ ] )}^{4} - 0.000169042249445724 \times {( L T - θ [ deg . ] )}^{2} - 0.00002693791947095 \; 46 \times {( LT - θ [ deg . ] )}^{3} + 3.947144804449 \times {10}^{- 7} \times {( LT - θ [ deg . ] )}^{4} - 0.0 \; 000000021152871909 \times {( L T - θ [ deg . ] )}^{5} + 4.03836185605311 e - 12 \times {( LT - θ [ deg . ] )}^{6} - 1.69037884352508 \times {( SiO2 [ λ ] )}^{2} + 0.850086542485958 \times {( SiO2 [ λ ] )}^{3} - 0.0374901951712912 \times ( LT [ λ ] ) \times ( L T - θ [ d e g . ] ) - 0.00155144508993598 \times ( L T - θ [ deg . ] ) \times ( SiO2 [ λ ] ) \qquad Equation 5$$

LT, SiO2, and LT-θ are preferably thicknesses and an angle in a range in which Rayleigh_ksaw² derived from Equation 5 is equal to or less than about 0.5%, for example. LT, SiO2, and LT-θ are more preferably thicknesses and an angle in a range in which Rayleigh_ksaw² derived from Equation 5 is equal to or less than about 0.2%, and further preferably thicknesses and an angle in a range in which Rayleigh_ksaw² derived from Equation 5 is equal to or less than about 0.1%, for example. As a result, unnecessary waves can be effectively reduced or prevented.

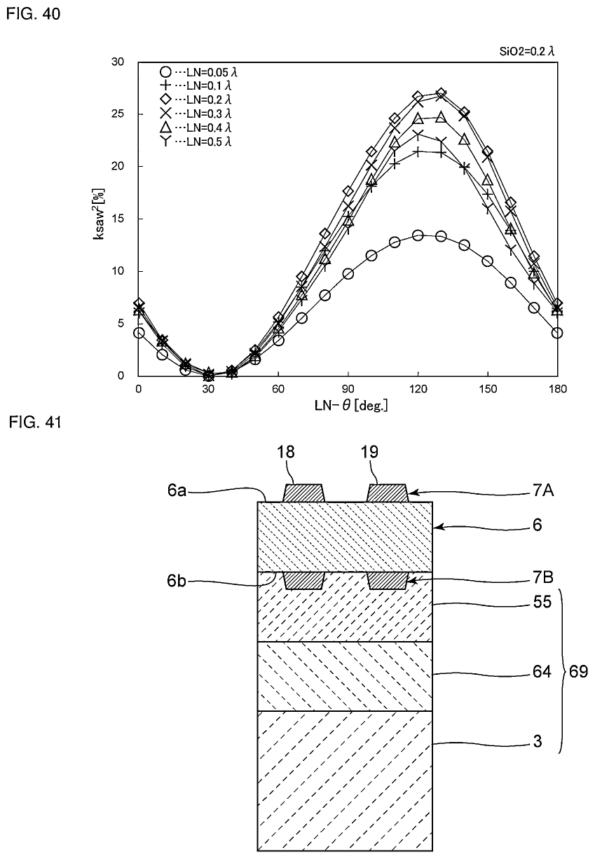

As described above, the piezoelectric layer 6 may be a lithium niobate layer. Also in this case, the electromechanical coupling coefficient ksaw² in the SH mode depends on θ in the Euler angles (φ, θ, ψ) and a thickness of the lithium niobate layer and the thickness of the dielectric layer 55. This example will be described by using FIG. 40. Note that θ and thickness of the lithium niobate layer and the thickness of the dielectric layer 55 were varied in the same manner as in the examples illustrated in FIGS. 38 and 39.

FIG. 40 is a diagram illustrating a relationship between θ in the Euler angles and the thickness of the lithium niobate layer and the electromechanical coupling coefficient ksaw² in the SH mode. The results illustrated in FIG. 40 are the results when the thickness of the dielectric layer 55 is about 0.2λ, for example. Note that, in FIG. 40, LN [λ] represents the thickness of the lithium niobate layer.

As illustrated in FIG. 40, the electromechanical coupling coefficient ksaw² in the SH mode depends on θ in the Euler angles and the thickness of the lithium niobate layer and the thickness of the dielectric layer 55. Note that, also in a case where the piezoelectric layer 6 is the lithium niobate layer, the electromechanical coupling coefficient ksaw² in the SH mode can be suitably adjusted when the thickness of the lithium niobate layer is equal to or more than about 0.05λ and equal to or less than about 0.5λ, for example. When the dielectric layer 55 is more than about 0λ and equal to or less than about 0.5λ, for example, the electromechanical coupling coefficient ksaw² in the SH mode can be increased and suitably adjusted.

The thickness of the lithium niobate layer is represented by LN [λ], and θ in the Euler angles (φ, θ, ψ) of the lithium niobate layer is represented by LN-θ [deg.]. Equation 6, which is a relational expression between LN, SiO2, LN-θ, and SH_ksaw², was derived by simulation.

$${{{{SH\_ksaw}^{2} [ \% ] = ( - 5.38971658869739 ) + 161.846645657576 \times ( L N [ λ ] ) - 0.36580242489511 \times ( L N - θ [ deg . ] ) + 23.9085116998593 \times ( SiO 2 [ λ ] ) - 75 \; 9.6024146374 \; 39 \times {( L N [ λ ] )}^{2} + 1439.87480037156 \times {( L N [ λ ] )}^{3} - 995.632600964584 \times {( L N [ λ ] )}^{4} + 0.00603298240934577 \times {( L N - θ [ deg . ] )}^{2} - 0.0000222875633447991 \times {( L N - θ [ deg . ] )}^{3} + 5.166408739753 \times {10}^{- 7} \times ( L N - θ [ deg . ] ) - 0. 0000000059686440 \; 638 \times {( L N - θ [ deg . ] )}^{5} + 1.71640061067492 e - 11 \times {( L N - θ [ deg . ] )}^{6} - 93. 70529550023 \; 45 \times ( SiO 2 ) [ λ ] )}^{2} 168.254832299343 \times {( SiO 2 [ λ ] )}^{3} - 143.019681373797 \times ( SiO 2 ) [ λ ] )}^{4} + 46.3787373260216 \times ( SiO 2 ) [ λ ] )}^{5} + 0.0440914074841534 \times ( L N [ λ ] ) \times ( L N - θ [ deg . ] ) - 2.70467523534839 \times ( L N [ λ ] ) \times ( SiO2 λ ] ) \qquad Equation 5$$

LN, SiO2, and LN-θ are preferably thicknesses and an angle in a range in which SH_ksaw² derived from Equation 6 is equal to or more than about 5%, for example. Thus, the acoustic wave device can be suitably used in a filter device. LN, SiO2, and LN-θ are more preferably thicknesses and an angle in a range in which SH_ksaw² derived from Equation 6 is equal to or more than about 10%, and further preferably thicknesses and an angle in a range in which SH_ksaw² derived from Equation 6 is equal to or more than about 15%, for example. As a result, when the acoustic wave device is used in a filter device, insertion loss can be reduced. It is even more preferable that LN, SiO2, and LN-θ be thicknesses and an angle in a range in which SH_ksaw² derived from Equation 6 is equal to or more than about 20%, for example. Thus, when the acoustic wave device is used in a filter device, insertion loss can be further reduced.

Equation 7, which is a relational expression between LN, SiO2, LN-θ, and Rayleigh_ksaw², was derived by simulation.

$${Rayleigh\_ksaw}^{2} [ \% ] = ( - 4.22213724365062 ) + 4.83829560339829 \times ( L N [ λ ] ) + 0.279393806354926 \times ( L N - θ [ deg . ] ) + 0.807049789687486 \times ( SiO 2 [ λ ] ) + 268. 9901 \; 11547116 \times {( L N [ λ ] )}^{2} - 766.61204369316 \times {( L N [ λ ] )}^{3} + 620.443142571277 \times {( L N [ λ ] )}^{4} - 0.0107426138393096 \times {( L N - θ [ deg . ] )}^{2} + 0.000288176932074345 \times {( L N - θ [ deg . ] )}^{3} - 0.0000036182410887836 \times {( L N - θ [ deg . ] )}^{4} + 1.97351506609 \times {10}^{- 8} \times {( L N - θ [ deg . ] )}^{5} - 3.843810801305 e - 11 \times {( L N - θ [ d e g . ] )}^{6} - 0.125547103958321 \times ( L N [ λ ] ) \times ( L N - θ [ d e g . ] ) - 0.00625388844904114 \times ( L N - θ [ d e g . ] ) \times ( SiO2 [ λ ] ) \qquad Equation 7$$

LN, SiO2, and LN-G are preferably thicknesses and an angle in a range in which Rayleigh_ksaw² derived from Equation 7 is equal to or less than about 0.5%, for example. LN, SiO2, and LN-G are more preferably thicknesses and an angle in a range in which Rayleigh_ksaw² derived from Equation 7 is equal to or less than about 0.2%, and further preferably thicknesses and an angle in a range in which Rayleigh_ksaw² derived from Equation 7 is equal to or less than about 0.1%, for example. As a result, unnecessary waves can be effectively reduced or prevented.

FIG. 41 is a schematic elevational cross-sectional view illustrating a vicinity of a pair of electrode fingers of each of a first IDT electrode and a second IDT electrode in an acoustic wave device according to a fifth preferred embodiment.

The present preferred embodiment is different from the fourth preferred embodiment in that a support 69 includes a plurality of dielectric layers. Except for the above point, the acoustic wave device of the present preferred embodiment has the same configuration as that of the acoustic wave device of the fourth preferred embodiment.

To be more specific, a high acoustic velocity layer 64 as a first dielectric layer is provided on a support substrate 3. A dielectric layer 55 is provided on the high acoustic velocity layer 64 as a second dielectric layer. Note that the support substrate 3, the dielectric layer 55, and the high acoustic velocity layer 64 may be laminated in this order. The number of layers of the dielectric layer is not particularly limited thereto. At least one layer of the dielectric layer may be provided between the support substrate 3 and the piezoelectric layer 6.

The high acoustic velocity layer 64 is a layer having a relatively high acoustic velocity. An acoustic velocity of a bulk wave propagating through the high acoustic velocity layer 64 is higher than an acoustic velocity of an acoustic wave propagating through the piezoelectric layer 6. In the present preferred embodiment, the high acoustic velocity layer 64 is a silicon nitride layer. However, the material of the high acoustic velocity layer 64 is not limited to the above, for example, a medium containing the above material as a main component such as silicon, aluminum oxide, silicon carbide, silicon oxynitride, sapphire, lithium tantalate, lithium niobate, a quartz crystal, alumina, zirconia, cordierite, mullite, steatite, forsterite, magnesia, a diamond-like carbon (DLC) film, diamond, or the like can be used.

Also in the present preferred embodiment, as in the fourth preferred embodiment, it is possible to reduce or prevent fluctuations in the electrical characteristics due to a change in the shape of the piezoelectric layer 6, and to reduce or prevent the higher-order modes.

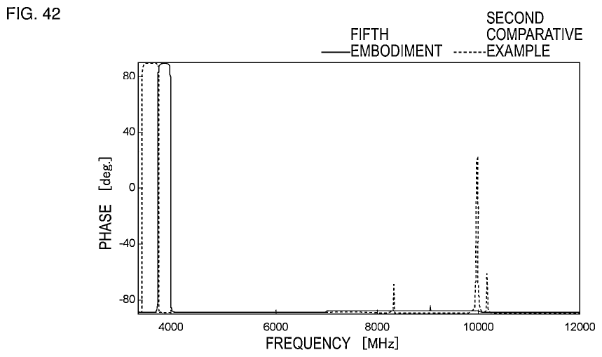

In the fifth preferred embodiment, the phase characteristics were obtained by performing simulation. Design parameters of the acoustic wave device were as follows. FIG. 42 illustrates the phase characteristics together with the phase characteristics of the second comparative example. In the second comparative example, a portion of the piezoelectric layer 6 overlapping the intersection region in plan view is not laminated with a support.
Support substrate 3; material: Si, plane orientation: (100) plane
High acoustic velocity layer 64; material: Si₃N₄, thickness: 0.45λ
Dielectric layer 55; material: SiO₂, thickness: 0.27λ
Piezoelectric layer 6; material: LiTaO₃, cut-angles: 30° Y-cut X-propagation, thickness: 0.2λ
Orientation relationship between the support substrate 3 and the piezoelectric layer 6; the Si [110] direction and the X_{Li} axis direction are parallel to each other.
First IDT electrode 7A; material: Al, thickness: 0.07λ, duty ratio: 0.5
Second IDT electrode 7B; material: Al, thickness: 0.07 λ, duty ratio: 0.5
Wavelength λ: 1 μm

FIG. 42 is a diagram illustrating the phase characteristics in the fifth preferred embodiment and the second comparative example.

As illustrated in FIG. 42, a plurality of higher-order modes is generated in the second comparative example. In contrast, it is understood that the higher-order modes are reduced or prevented in the present preferred embodiment. Note that it is known that the higher-order modes are also reduced or prevented when the material and the thickness of the high acoustic velocity layer 64 are changed.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer provided on the support and including a first principal surface and a second principal surface facing each other;
a first IDT electrode provided on the first principal surface and including a plurality of electrode fingers; and
a second IDT electrode provided on the second principal surface and including a plurality of electrode fingers; wherein
the second IDT electrode is embedded in the support;
a dielectric film is provided on the first principal surface of the piezoelectric layer to cover the first IDT electrode; and
when a wavelength defined by an electrode finger pitch of the first IDT electrode is represented by λ, a thickness of the dielectric film is equal to or less than about 0.15λ.

2. The acoustic wave device according to claim 1, wherein the thickness of the dielectric film is equal to or less than about 0.05λ.

3. An acoustic wave device comprising:
a support including a support substrate;
a piezoelectric layer provided on the support and including a first principal surface and a second principal surface facing each other;
a first IDT electrode provided on the first principal surface and including a plurality of electrode fingers; and
a second IDT electrode provided on the second principal surface and including a plurality of electrode fingers; wherein
the second IDT electrode is embedded in the support; and
a film covering the first IDT electrode is not provided on the first principal surface of the piezoelectric layer.

4. The acoustic wave device according to claim 1, wherein at least a portion of the plurality of electrode fingers of the first IDT electrode and at least a portion of the plurality of electrode fingers of the second IDT electrode overlap each other in plan view, and the electrode fingers overlapping each other in plan view are connected to a same potential.

5. The acoustic wave device according to claim 1, further comprising an insulation layer provided between the piezoelectric layer and at least one of the first IDT electrode and the second IDT electrode.

6. The acoustic wave device according to claim 1, wherein
each of the first IDT electrode and the second IDT electrode includes a plurality of electrode fingers;
in each of the first IDT electrode and the second IDT electrode, when viewed from an acoustic wave propagation direction, a region in which adjacent ones of the electrode fingers overlap each other is an intersection region, and when a direction in which the plurality of electrode fingers extends is referred to as an electrode finger extending direction, the intersection region includes a central region located on a central side in the electrode finger extending direction and a first edge region and a second edge region facing each other with the central region in between in the electrode finger extending direction; and
in at least one of the first IDT electrode and the second IDT electrode, acoustic velocities in the first edge region and the second edge region are lower than an acoustic velocity in the central region.

7. The acoustic wave device according to claim 1, wherein
the acoustic wave device is structured to generate a shear horizontal mode; and
when the electrode finger pitch of the first IDT electrode and an electrode finger pitch of the second IDT electrode are equal, a wavelength defined by the electrode finger pitches of the first IDT electrode and the second IDT electrode is represented by λ, a thickness of the first IDT electrode is represented by IDTu [λ], a thickness of the second IDT electrode is represented by IDTd [λ], a density of the first IDT electrode is represented by ρ1 [g/cm³], a density of the second IDT electrode is represented by ρ2 [g/cm³], and a fractional bandwidth of a shear horizontal is represented by SH_BW [%], IDTu, IDTd, ρ1, and ρ2 are thicknesses and densities in ranges in which SH_BW derived from Equation 1 below is equal to or more than about 3%:
$${SH\_BW [ \% ] = 4.94 28834786 \; 9583 - 1.37989369528872 \times ( I DTd [ λ ] \times ρ2 [ g / {cm}^{3} ] ) + 1. 813184606833 \times ( IDTu [ λ ] \times ρ1 [ g / {cm}^{3} ] ) + 2.51396812128047 \times {( IDTd [ λ ] \times ρ2 [ g / {cm}^{3} ] )}^{2} - 2.28238205352 \; 906 \times {( IDTd [ λ ] \times ρ2 [ g / {cm}^{3} ] )}^{3} + 0.61094393501087 \times {( IDTd [ λ ] \times ρ2 [ g / {cm}^{3} ] )}^{4} - 22.6347858439936 \times {( IDTu [ λ ] \times ρ1 [ g / {cm}^{3} ] )}^{2} + 63.86 32598480 \; 415 \times {( IDTu [ λ ] \times ρ1 [ g / {cm}^{3} ] )}^{3} - 74. 1181743703044 \times {( IDTu [ λ ] \times ρ1 [ g / {cm}^{3} ] )}^{4} + 37.9952058002712 \times {( IDTu [ λ ] \times ρ1 [ g / cm )}^{3} ] )}^{5} - 7.14595960324194 \times {( IDTu [ λ ] \times ρ1 [ g / {cm}^{3} ] )}^{6} + 0.588480822096255 \times ( IDTd [ λ ] \times ρ2 [ g / {cm}^{3} ] ) ( IDTu [ λ ] \times ρ1 [ g / {cm}^{3} ] ) . \qquad Equation 1$$

8. The acoustic wave device according to claim 1, wherein a density of the second IDT electrode is greater than a density of the first IDT electrode.

9. The acoustic wave device according to claim 1, wherein at least one of the first IDT electrode and the second IDT electrode is made of Pt.

10. The acoustic wave device according to claim 8, wherein the first IDT electrode is made of Al, and the second IDT electrode is made of Pt.

11. The acoustic wave device according to claim 1, wherein
the acoustic wave device is structured to generate a shear horizontal mode; and
when a duty ratio of the first IDT electrode is represented by duty_u, a duty ratio of the second IDT electrode is represented by duty_d, and a fractional bandwidth of the Shear horizontal mode is represented by SH_BW [%], duty_u and duty_d are duty ratios in a range in which SH_BW derived from Equation 2 below is equal to or more than about 4%:
$$SH\_BW [ \% ] = 4.82349577998388 - 3.61425920727189 \times duty\_u - 1.56118181746504 \times duty\_d + 13.3830411409058 \times {duty\_u}^{2} - 12.0401956788195 \times {duty\_u}^{3} + 6.29516073499509 \times {duty\_d}^{2} - 8.10795949927642 \times {duty\_d}^{3} . \qquad Equation 2$$

12. The acoustic wave device according to claim 1,
wherein when a duty ratio of the first IDT electrode is represented by duty_u, and a duty ratio of the second IDT electrode is represented by duty_d, duty_u and duty_d are duty ratios in a range in which a phase of an unnecessary wave derived from Equation 3 below is equal to or less than about −30 degrees:
Phase of unnecessary wave [deg.]=69.4+162.7×duty_d−136.7×duty_u−179.6×duty_d²−108.2×duty_u²+164.2×duty_d×duty_u Equation 3.

13. The acoustic wave device according to claim 1, wherein the piezoelectric layer is a lithium tantalate layer or a lithium niobate layer.

14. The acoustic wave device according to claim 1, wherein the support includes at least one dielectric layer provided between the support substrate and the piezoelectric layer.

15. The acoustic wave device according to claim 14, wherein
the at least one dielectric layer includes a high acoustic velocity layer; and
an acoustic velocity of a bulk wave propagating through the high acoustic velocity layer is higher than an acoustic velocity of an acoustic wave propagating through the piezoelectric layer.

16. The acoustic wave device according to claim 14, wherein the at least one dielectric layer includes a silicon oxide layer.

17. The acoustic wave device according to claim 16, wherein
a dielectric layer which is the silicon oxide layer is directly laminated on the piezoelectric layer;
the piezoelectric layer is a lithium tantalate layer;
the acoustic wave device is structured to generate a shear horizontal mode; and
when the electrode finger pitch of the first IDT electrode and an electrode finger pitch of the second IDT electrode are equal, a wavelength defined by the electrode finger pitches of the first IDT electrode and the second IDT electrode is represented by λ, a thickness of the piezoelectric layer is represented by LT [λ], a thickness of the dielectric layer is represented by SiO2 [λ], θ in Euler angles (φ, θ, ψ) of the piezoelectric layer is represented by LT-θ [deg.], and an electromechanical coupling coefficient in the Shear horizontal mode is represented by SH_ksaw² [%], LT, SiO2, and LT-θ are thicknesses and an angle in ranges in which SH_ksaw² derived from Equation 4 below is equal to or more than about 6%:
$${SH\_ksaw}^{2} [ \% ] = - 2.42187620828543 + 62.484281524666 \times ( LT [ λ ] ) - 0.107924507780421 \times ( LT - θ [ deg . ] ) + 8.9 0369850943 \; 586 \times ( SiO2 [ λ ] ) - 268. 852679355 \; 883 \times {( LT [ λ ] )}^{2} + 499.449089766496 \times {( L T [ λ ] )}^{3} - 350.106860593976 \times {( L T [ λ ] )}^{4} - 0.00180396948527691 \times {( LT - θ [ deg . ] )}^{2} + 0.000124241019900316 \times {( LT - θ [ deg . ] )}^{3} - 0. 000013970722975499 \times {( LT - θ [ deg . ] )}^{4} + 5.8624484454 \times {10}^{- 9} \times {( L T - θ [ deg . ] )}^{5} - 8.4861389677363 e - 12 \times {( L T - θ [ d e g . ] )}^{6} - 38.0582687313641 \times {( SiO 2 [ λ ] )}^{2} + 71.3862412045158 \times {( SiO2 [ λ ] )}^{3} - 62.6002863635122 \times {( SiO 2 [ λ ] )}^{4} + 20.7954101598776 \times {( SiO2 [ λ ] )}^{5} + 0. 175104581123753 \times ( L T [ λ ] ) \times ( LT - θ [ deg . ] ) . \qquad Equation 4$$

18. The acoustic wave device according to claim 16, wherein
a dielectric layer which is the silicon oxide layer is directly laminated on the piezoelectric layer;
the piezoelectric layer is a lithium tantalate layer;
the acoustic wave device is structured to generate a shear horizontal mode; and
when the electrode finger pitch of the first IDT electrode and an electrode finger pitch of the second IDT electrode are equal, a wavelength defined by the electrode finger pitches is represented by λ, a thickness of the piezoelectric layer is represented by LT [λ], a thickness of the dielectric layer is represented by SiO2 [λ], θ in Euler angles (φ, θ, φ) of the piezoelectric layer is represented by LT-θ [deg.], and an electromechanical coupling coefficient in a Rayleigh mode is represented by Rayleigh_ksaw² [%], LT, SiO2, and LT-θ are thicknesses and an angle in ranges in which Rayleigh_ksaw² derived from Equation 5 below is equal to or less than about 0.5%:
$${Rayleigh\_ksaw}^{2} [ \% ] = ( - 0.986147947509026 ) - 4.8091444146841 \times ( LT [ λ ] ) + 0.0696242386883329 \times ( L T - θ ) [ deg . ] ) + 1.19398580127017 \times ( SiO 2 [ λ ] ) + 103.399105364715 \times {( L T [ λ ] )}^{2} - 279.94327949742 \times {( L T [ λ ] )}^{3} + 227.888456729838 \times {( LT [ λ ] )}^{4} - 0.000169042249445724 \times {( LT - θ [ deg . ] )}^{2} - 0.0000269379194709546 \times {( LT - θ [ deg . ] )}^{3} + 0. 000003947144804449 \times {( LT - θ [ deg . ] )}^{4} - 2.1152871909 \times {10}^{- 9} \times {( L T - θ [ deg . ] )}^{5} + 4. 3836185605311 e - 12 \times {( L T - θ [ deg . ] )}^{6} - 1.69037884352508 \times {( SiO 2 [ λ ] )}^{2} + 0.850086542485958 \times {( SiO2 [ λ ] )}^{3} - 0. 3749019517129 \; 12 \times ( LT [ λ ] ) \times ( LT - θ [ deg . ] ) - 0.00155144508993598 \times ( LT - θ [ deg . ] ) \times ( SiO 2 [ λ ] ) . \qquad Equation 5$$

19. The acoustic wave device according to claim 16, wherein
a dielectric layer which is the silicon oxide layer is directly laminated on the piezoelectric layer;
the piezoelectric layer is a lithium niobate layer;
the acoustic wave device is structured to generate a shear horizontal mode; and
when the electrode finger pitch of the first IDT electrode and an electrode finger pitch of the second IDT electrode are equal, a wavelength defined by the electrode finger pitches is represented by λ, a thickness of the piezoelectric layer is represented by LN [λ], a thickness of the dielectric layer is represented by SiO₂ [λ], θ in Euler angles (φ, θ, ψ) of the piezoelectric layer is represented by LN-θ [deg.], and an electromechanical coupling coefficient in the Shear horizontal mode is represented by SH_ksaw² [%], LN, SiO2, and LN-θ are thicknesses and an angle in ranges in which SH_ksaw² derived from Equation 6 below is equal to or more than about 5%:
$${SH\_ksaw}^{2} [ \% ] = ( - 5.38971658869439 ) + 161.846645657576 \times ( L N [ λ ] ) - 0.36580242489511 \times ( L N - θ [ d e g . ] ) + 23.9085116998593 \times ( SiO2 [ λ ] ) - 759. 602414637 \; 439 \times {( L N [ λ ] )}^{2} + 1439.87480037156 \times {( L N [ λ ] )}^{3} - 995.632600964584 \times {( L N [ λ ] )}^{4} + 0. 0603298240934 \; 577 \times {( L N - θ [ deg . ] )}^{2} - 0.0000222875633447991 \times {( L N - θ [ ( deg . ] )}^{3} + 5.166408739753 \times {10}^{- 7} \times {( L N - θ [ deg . ] )}^{4} - 5.9686440638 \times {10}^{- 9} \times {( L N - θ [ deg . ] )}^{5} + 1.71640061067492 e - 11 \times {( L N - θ [ deg . ] )}^{6} - 93.7052955002345 \times {( SiO2 [ λ ] )}^{2} + 168.254832299343 \times {( SiO2 [ λ ] )}^{3} - 143.019681373797 \times {( SiO2 [ λ ] )}^{4} + 46.3787373260216 \times {( SiO2 [ λ ] )}^{5} + 0.0440914074841534 \times ( L N [ λ ] ) \times ( L N - θ [ deg . ] ) - 2.70467523534839 \times ( L N [ λ ] ) \times ( SiO2 [ λ ] ) . \qquad Equation 6$$

20. The acoustic wave device according to claim 16, wherein
a dielectric layer which is the silicon oxide layer is directly laminated on the piezoelectric layer;
the piezoelectric layer is a lithium niobate layer;
the acoustic wave device is structured to generate a shear horizontal mode; and
when the electrode finger pitch of the first IDT electrode and an electrode finger pitch of the second IDT electrode are equal, a wavelength defined by the electrode finger pitches is represented by λ, a thickness of the piezoelectric layer is represented by LN [λ], a thickness of the dielectric layer is represented by SiO2 [λ], θ in Euler angles (φ, θ, ψ) of the piezoelectric layer is represented by LN-θ [deg.], and an electromechanical coupling coefficient in a Rayleigh mode is represented by Rayleigh_ksaw² [%], LN, SiO2, and LN-θ are thicknesses and an angle in ranges in which Rayleigh_ksaw² derived from Equation 7 below is equal to or less than about 0.5%:
$${Rayleigh\_ksaw}^{2} [ \% ] = ( - 4.22213724365062 ) + 4.83829560339829 \times ( L N [ λ ] ) + 0.279393806354926 \times ( L N - θ [ deg . ] ) + 0.807049789687486 \times ( SiO 2 [ λ ] ) + 268. 9901 \; 11547116 \times {( L N [ λ ] )}^{2} - 766.61204369316 \times {( L N [ λ ] )}^{3} + 620.443142571277 \times {( L N [ λ ] )}^{4} - 0.0107426138393096 \times {( L N - θ [ deg . ] )}^{2} + 0.000288176932074345 \times {( L N - θ [ deg . ] )}^{3} - 0.0000036182410887836 \times {( L N - θ [ deg . ] )}^{4} + 1.97351506609 \times {10}^{- 8} \times {( L N - θ [ deg . ] )}^{5} - 3.843810801305 e - 11 \times {( L N - θ [ d e g . ] )}^{6} - 0.125547103958321 \times ( L N [ λ ] ) \times ( L N - θ [ d e g . ] ) - 0.00625388844904114 \times ( L N - θ [ d e g . ] ) \times ( SiO2 [ λ ] ) . \qquad Equation 7$$

21. The acoustic wave device according to claim 16, wherein
the piezoelectric layer is a lithium tantalate layer or a lithium niobate layer;
a thickness of the piezoelectric layer is equal to or more than about 0.05λ and equal to or less than about 0.5λ; and
a thickness of a dielectric layer which is the silicon oxide layer is more than about 0λ and equal to or less than about 0.5λ.

22. The acoustic wave device according to claim 1, wherein the piezoelectric layer is directly provided on the support substrate.

23. The acoustic wave device according to claim 1, wherein
each of the first IDT electrode and the second IDT electrode includes a pair of busbars; and
a through electrode that penetrates the piezoelectric layer and connects one of the busbars of the first IDT electrode and one of the busbars of the second IDT electrode is further included.

24. The acoustic wave device according to claim 1, wherein the support substrate is a silicon substrate.
